(19) United States
(12) Patent Application Publication
(10) Pub. No.: US 2026/0362930 A1
(43) Pub. Date: Nov. 12, 2026

(54) ARRAY SUBSTRATE, DISPLAY PANEL, DISPLAY DEVICE AND COLOR-FILTER STRUCTURE DETECTION METHOD

(71) Applicant: Shanghai AVIC Optoelectronics Co., Ltd., Shanghai (CN)

(72) Inventor: Huijun JIN, Shanghai (CN)

(73) Assignee: Shanghai AVIC Optoelectronics Co., Ltd., Shanghai (CN)

(21) Appl. No.: 19/723,977

(22) Filed: Jun. 29, 2026

(30) Foreign Application Priority Data
Dec. 31, 2025 (CN) 202512060983.9

(51) Int. Cl. H10K 59/38; H10K 59/126; H10K 59/131; H10P 74/20

(52) U.S. Cl. CPC H10K 59/38; H10K 59/126; H10K 59/131; H10P 74/203

(57) ABSTRACT

An array substrate includes a substrate, a light-emitting functional layer including pixel columns and data signal lines both arranged along first direction and extending along second direction, a color-filter layer including a color-filter structure, and first light-shielding lines located on a side of the color-filter layer facing the substrate and arranged along the first direction and extending along the second direction. At least one data signal line is electrically connected to sub-pixels in two of the multiple pixel columns. On a plane of the substrate, orthographic projections of the data signal lines overlap orthographic projections of the first light-shielding lines. The color-filter structure includes a first edge and a second edge arranged opposite to each other along the first direction. On a plane of the substrate, orthographic projections of the first edge and the second edge overlap the orthographic projections of the first light-shielding lines.

### CROSS-REFERENCE TO RELATED APPLICATION(S)

This application claims priority to Chinese Patent Application No. 202512060983.9 filed Dec. 31, 2025, the disclosure of which is incorporated herein by reference in its entirety.

### TECHNICAL FIELD

The present disclosure relates to the technical field of display technologies, in particular to an array substrate, a display panel, a display device, and a color-filter structure detection method.

### BACKGROUND

With the development of display technologies, Color-filter on Array (COA) technology has been developed. In COA technology, color-filter structures are fabricated on a thin-film transistor (TFT) array substrate. The color-filter structures include color-filter units of multiple colors, thereby forming sub-pixels of different colors.

To improve display performance and product yield, the color-filter structures in the array substrate need to be monitored. However, in the related art, the detection efficiency and accuracy for the color-filter structures are relatively low.

Therefore, how to efficiently and accurately identify alignment abnormalities of the color-filter structures has become an urgent technical problem to be solved.

### SUMMARY

The present disclosure provides an array substrate, a display panel, a display device and a color-filter structure detection method to improve the detection efficiency and accuracy of the color-filter structure.

According to an aspect of the present disclosure, an array substrate is provided and includes a substrate, a light-emitting functional layer at a side of the substrate, and a color-filter layer at a side of the light-emitting functional layer facing away from the substrate.

The light-emitting functional layer includes multiple pixel columns arranged along a first direction and extending along a second direction and multiple data signal lines arranged along the first direction and extending along the second direction. The first direction intersects the second direction, and both the first direction and the second direction are parallel to a plane of the substrate. The pixel column includes multiple sub-pixels arranged along the second direction. At least one data signal line is electrically connected to sub-pixels in two of the multiple pixel columns.

The array substrate further includes multiple first light-shielding lines located on a side of the color-filter layer facing the substrate, arranged along the first direction and extending along the second direction. Orthographic projections of the multiple data signal lines on the plane of the substrate overlap orthographic projections of the multiple first light-shielding lines on the plane of the substrate.

The color-filter layer is located in a display area and includes multiple color-filter structures. An orthographic projection of one color-filter structure on the plane of the substrate overlaps orthographic projections of the multiple sub-pixels on the plane of the substrate. The color-filter structure includes a first edge and a second edge arranged opposite to each other along the first direction. An orthographic projection of the first edge and an orthographic projection of the second edge on the plane of the substrate overlap the orthographic projections of the multiple first light-shielding lines on the plane of the substrate.

According to another aspect of the present disclosure, a display panel is provided and includes the array substrate of any one of the above embodiments.

According to another aspect of the present disclosure, a display device is provided and includes the display panel of any one of the above embodiments.

According to another aspect of the present disclosure, a color-filter structure detection method for the array substrate of any one of the above embodiments is provided.

The color-filter structure detection method includes the following:

An array substrate is provided. The array substrate includes the substrate, the light-emitting functional layer located on the side of the substrate, and the color-filter layer located on the side of the light-emitting functional layer facing away from the substrate.

A light source is provided on a side of the substrate facing away from the color-filter layer. Light from the light source passes through the substrate, the light-emitting functional layer, and the color-filter layer sequentially.

The array substrate is captured at a side of the color-filter layer facing away from the substrate to acquire a detection image.

Whether a color-filter structure of the multiple color-filter structures in the color-filter layer is misaligned is determined based on contours of the multiple color-filter structures and contours of the multiple first light-shielding lines in the detection image.

### BRIEF DESCRIPTION OF DRAWINGS

To illustrate the solutions in the embodiments of the present disclosure more clearly, the embodiments are described hereinafter through description in conjunction with the drawings. Apparently, the drawings described herein are part of the embodiments of the present disclosure, and based on the drawings of the present disclosure, all other drawings may be acquired by those of ordinary skill in the art on the premise that no creative work is done.

FIG. 1 is a schematic diagram of a film layer structure of an array substrate according to an embodiment of the present disclosure.

FIG. 2 is a schematic top view of an array substrate according to an embodiment of the present disclosure.

FIG. 3 is another schematic top view of an array substrate according to an embodiment of the present disclosure.

FIG. 4 is another schematic diagram of a film layer structure of an array substrate according to an embodiment of the present disclosure.

FIG. 5 is another schematic top view of an array substrate according to an embodiment of the present disclosure.

FIG. 6 is another schematic top view of an array substrate according to an embodiment of the present disclosure.

FIG. 7 is another schematic top view of an array substrate according to an embodiment of the present disclosure.

FIG. 8 is another schematic top view of an array substrate according to an embodiment of the present disclosure.

FIG. 9 is another schematic top view of an array substrate according to an embodiment of the present disclosure.

FIG. 10 is another schematic top view of an array substrate according to an embodiment of the present disclosure.

FIG. 11 is another schematic top view of an array substrate according to an embodiment of the present disclosure.

FIG. 12 is another schematic top view of an array substrate according to an embodiment of the present disclosure.

FIG. 13 is another schematic top view of an array substrate according to an embodiment of the present disclosure.

FIG. 14 is an enlarged schematic diagram of a local area LA in FIG. 13.

FIG. 15 is another enlarged schematic diagram of a local area LA in FIG. 13.

FIG. 16 is another schematic diagram of a film layer structure of an array substrate according to an embodiment of the present disclosure.

FIG. 17 is another schematic diagram of a film layer structure of an array substrate according to an embodiment of the present disclosure.

FIG. 18 is another schematic diagram of a film layer structure of an array substrate according to an embodiment of the present disclosure.

FIG. 19 is another schematic top view of an array substrate according to an embodiment of the present disclosure.

FIG. 20 is a flow chart of a color-filter structure detection method of an array substrate according to an embodiment of the present disclosure.

FIG. 21 is another flow chart of a color-filter structure detection method of an array substrate according to an embodiment of the present disclosure.

FIG. 22 is a structural schematic diagram of a display panel according to an embodiment of the present disclosure.

FIG. 23 is a structural schematic diagram of a display device according to an embodiment of the present disclosure.

### DETAILED DESCRIPTION

To enable those skilled in the art to better understand the solutions of the present disclosure, the solutions in the embodiments of the present disclosure are described clearly and completely hereinafter in conjunction with the drawings in the embodiments of the present disclosure. Apparently, the embodiments described herein are only part of the embodiments of the present disclosure, but not all of the embodiments, and based on the embodiments of the present disclosure, all other embodiments acquired by those of ordinary skill in the art on the premise that no creative work is done are within the scope of the present disclosure.

It should be noted that the terms “first” and “second” in the description, claims and the above drawings of the present disclosure are used to distinguish similar objects, and are not necessarily used to describe a specific order or sequence. It should be understood that the numbers used in this way may be interchanged where appropriate, so that the embodiments of the present disclosure described herein may be implemented in an order other than those illustrated or described herein. Furthermore, the terms “including” and “comprising” and any variations thereof are intended to cover non-exclusive inclusion, for example, a process, method, system, product or device that includes a series of steps or elements is not necessarily limited to those steps or elements expressly listed, but may include other steps or elements not expressly listed or inherent to such process, method, product or device.

In the related art, an alignment abnormality detection method of the color-filter structure is provided. A detection area is provided in a non-display area of an array substrate, and an auxiliary measurement pattern is formed in the detection area as a measurement reference. An offset distance of a color-filter structure in a display area relative to the auxiliary measurement pattern is used to detect the offset distance of the color-filter structure in the detection area. In this manner, the auxiliary measurement pattern, serving as a reference for measuring the physical characteristics of the color-filter structure, is formed only between the to-be-detected color-filter structure and the substrate, thereby reducing the interference of the circuit structure and conductive lines of the array substrate on the color-filter structure and improving the detection accuracy. However, this detection method can only detect the overall alignment of the color-filter structure and cannot detect the local alignment abnormality caused by local differences during the fabrication process. For example, during the fabrication process of the color-filter structure, the color-filter structure is typically formed by photolithography, and the photolithography includes exposure, development, etching and other processes. Since environmental and equipment factors may cause a local temperature anomaly or an optical path abnormality during the exposure process, the shape and size of the local color-filter structure may be affected. Furthermore, uneven etching, over-etching, material anisotropy and other reasons may also cause a local shape abnormality and a size abnormality of the color-filter structure, and these local alignment abnormalities can not be detected.

In the related art, another alignment abnormality detection method of the color-filter structure is provided. A color-filter structure in a display area is directly detected by capturing the color-filter structure in the display area and measuring a distance between an edge of the color-filter structure in the display area and an edge of the reference object, thus determining whether the color-filter structure has alignment abnormality. This detection method can detect the local alignment abnormality caused by local differences during the fabrication process. However, since the display area contains numerous small-sized color-filter structures, and the overlapping of color-filter structures of different colors forms a black opaque area, accurate focusing is required to capture a clear image, and the lens of the visual imaging system focuses slowly, resulting in a long detection time and low detection efficiency. To meet the production demand and increase the production line cycle time, the detection time needs to be compressed. This results in the detection image of the visual imaging system in a state of incomplete focusing, which is prone to edge blurring. Moreover, since multiple conductive lines exist in the display area, if two conductive lines are close, ghosting and blurring may occur, and the conductive lines overlap the edge of the color-filter structure and the black opaque area, resulting in misjudgment of alignment abnormality detection and thus affecting the product yield.

In the related art, although the deviation of the color-filter structure in the non-display area is detected to avoid the interference of the circuit structure and the conductive lines on the color-filter structure and improve the detection accuracy, the local alignment abnormality of the color-filter structure cannot be detected. Although the color-filter structure of the display area is directly detected to detect the local alignment abnormality of the color-filter structure, the detection is susceptible to interference of the circuit structure and the conductive lines on the color-filter structure, and the detection accuracy is low. Furthermore, if accurate focusing is needed to improve the accuracy, the detection time is long, which hinders the detection efficiency and affects the production line cycle time. Therefore, the related art can not identify the alignment abnormality of the color-filter structure efficiently and accurately.

To solve the above technical problems, the embodiments of the present disclosure provide an array substrate. The array substrate includes the substrate, the light-emitting functional layer at the side of the substrate, and the color-filter layer at the side of the light-emitting functional layer facing away from the substrate. The light-emitting functional layer includes multiple pixel columns and multiple data signal lines arranged along the first direction and extending along the second direction. The first direction intersects the second direction. Both the first direction and the second direction are parallel to the plane of the substrate. The pixel column includes multiple sub-pixels arranged along the second direction. At least one data signal line is electrically connected to sub-pixels in two pixel columns. The array substrate further includes multiple first light-shielding lines located on the side of the color-filter layer facing the substrate, arranged along the first direction and extending along the second direction. The orthographic projections of the data signal lines on the plane of the substrate overlap the orthographic projections of the first light-shielding lines on the plane of the substrate. The color-filter layer is located in the display area and includes multiple color-filter structures. The orthographic projection of a color-filter structure on the plane of the substrate overlap the orthographic projections of the sub-pixels on the plane of the substrate. The color-filter structure includes a first edge and a second edge arranged opposite to each other along the first direction. The orthographic projection of the first edge and the orthographic projection of the second edge on the plane of the substrate overlap the orthographic projections of the first light-shielding lines on the plane of the substrate.

According to the technical solution of the present disclosure, at least one of the data signal lines are electrically connected to the sub-pixels in two pixel columns by using DGLD technology, so that a number of conductive lines in the display area can be reduced, facilitating reducing interference of the conductive lines on the alignment abnormality detection of the color-filter structure, and further improving the situation where the short distance between the two conductive lines causes ghosting and blurring of the detection image. The multiple first light-shielding lines are arranged along the first direction and extending along the second direction on the side of the color-filter layer facing the substrate, so that the alignment abnormality detection of the color-filter structure can be performed by using the multiple first light-shielding lines as references. The orthographic projections of the data signal lines on the plane of the substrate overlap the orthographic projections of the first light-shielding lines on the plane of the substrate, facilitating improving the detection accuracy, thereby avoiding the misjudgment of the alignment abnormality detection of the color-filter structure caused by the data signal lines. Furthermore, the orthographic projection of the first edge and the orthographic projection of the second edge of the color-filter structure on the plane of the substrate are configured to overlap the orthographic projections of the first light-shielding lines on the plane of the substrate, and this allows for the determination of alignment abnormality of the color-filter structure when the orthographic projection of the first edge or the orthographic projection of the second edge on the plane of the substrate does not overlap the orthographic projections of the first light-shielding lines on the plane of the substrate. Therefore, when the alignment abnormality detection of the color-filter structure is performed, only whether the abnormal protrusion along the first direction exists in the contour of the orthographic projection of the first light-shielding lines on the plane of the substrate, or whether a gap exists between the orthographic projection of the first edge or the the orthographic projection the second edge on the plane of the substrate and orthographic projections of the first light-shielding lines on the plane of the substrate needs to be determined, and whether the color-filter structure is misaligned is determined. Neither the first light-shielding lines need to be used as references to accurately measure the distance between the edge of the color-filter structure and the first light-shielding lines along the first direction, nor accurate focus in the detection process is required. The accurate detection of the color-filter structure in the display area can be implemented, simplifying the color-filter structure detection method and improving detection efficiency and accuracy.

The above is the core idea of the present disclosure. Based on the embodiments of the present disclosure, all other embodiments acquired by those of ordinary skill in the art on the premise that no creative work is done are within the scope of the present disclosure. The solutions in the embodiments of the present disclosure are described clearly and completely hereinafter in conjunction with the drawings in the embodiments of the present disclosure.

It should be noted that the embodiments provided by the present disclosure may be combined with each other without contradiction.

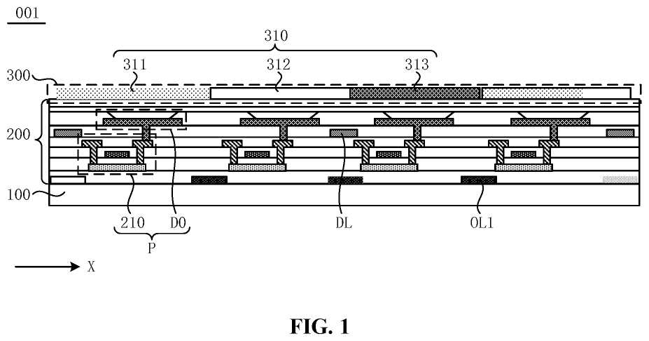

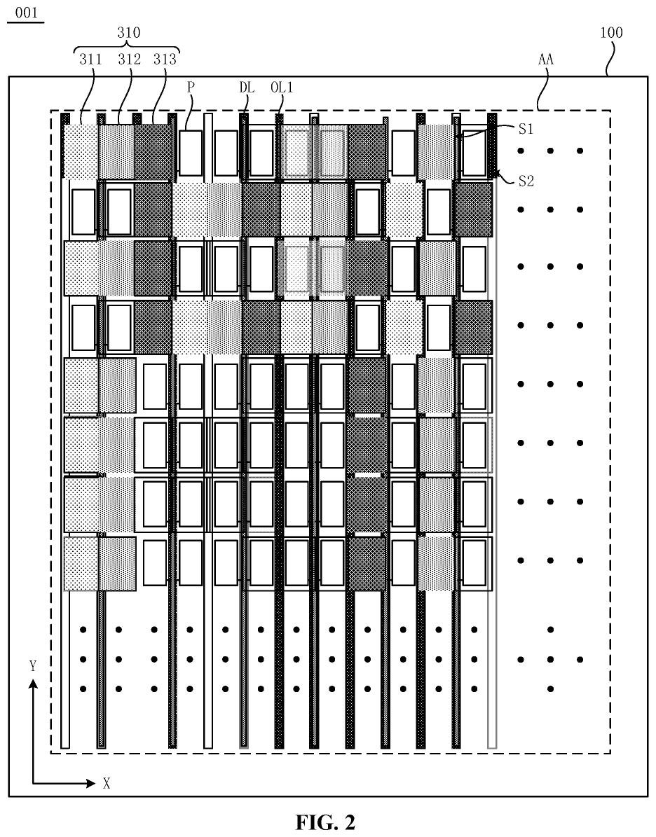

FIG. 1 is a schematic diagram of a film layer structure of an array substrate according to an embodiment of the present disclosure, and FIG. 2 is a schematic top view of an array substrate according to an embodiment of the present disclosure. Referring to FIGS. 1 and 2, an array substrate 001 includes a substrate 100, a light-emitting functional layer 200 at a side of the substrate, and a color-filter layer 300 at a side of the light-emitting functional layer 200 facing away from the substrate. The light-emitting functional layer 200 includes multiple pixel columns and multiple data signal lines DL arranged along a first direction X and extending along a second direction Y. The first direction X intersects the second direction Y. Both the first direction X and the second direction Y are parallel to a plane of the substrate 100. The pixel column includes multiple sub-pixels P arranged along the second direction Y. At least one data signal line DL is electrically connected to sub-pixels P in two pixel columns.

The substrate 100 may include a transparent substrate, a translucent substrate or an opaque substrate, and may include a rigid substrate or a flexible substrate. Furthermore, a side of the substrate 100 facing the light-emitting functional layer 200 may also include a buffer layer (not shown in FIG. 1) to block oxygen and moisture and provide a flat surface at the side of the substrate 100 facing the light-emitting functional layer 200. In one or more embodiments, the substrate 100 may be a transparent substrate, such as a glass substrate.

The light-emitting functional layer 200 includes a circuit layer and a light-emitting layer. The circuit layer includes multiple thin-film transistors, a pixel driving circuit 210 composed of thin-film transistors, conductive lines (such as data signal lines DL) for providing signals for the pixel driving circuit 210, and an interlayer dielectric layer disposed between conductive films. In one or more embodiments, the interlayer dielectric layer may be or may include a transparent and insulating material, such as silicon oxide and silicon nitride. In another alternative embodiment, the interlayer dielectric layer may also include an opaque and insulating material, such as non-conductive black particles, black pigment, or dark insulating material. The light-emitting layer includes multiple light-emitting elements D0, and the light-emitting elements D0 may be organic light-emitting diodes (OLEDs), Mini light-emitting diodes (LEDs), Micro LEDs, etc. The light-emitting elements D0 may be white light-emitting elements, red light-emitting elements, green light-emitting elements, blue light-emitting elements, etc. In an embodiment, the light-emitting layer and the light-emitting elements D0 thereof may be disposed on a side of the circuit layer facing away from the substrate 100. In one or more other embodiments, the light-emitting layer and the light-emitting elements D0 thereof may also be disposed on the side of the circuit layer facing the substrate 100 (not shown in FIG. 1). In one or more other embodiments, when the light-emitting elements D0 are OLEDs, a first electrode and a second electrode electrically connected thereto may both be transparent electrodes.

The pixel driving circuit 210 and the light-emitting elements D0 form a sub-pixel P, and the pixel driving circuit 210 provides a driving current to the light-emitting elements D0 according to the data signals transmitted by the data signal lines DL, so that the light-emitting elements D0 present a corresponding display grayscale. In one or more embodiments, an orthographic projection of the pixel driving circuit 210 on the plane of the substrate 100 does not overlap orthographic projections of the light-emitting elements D0 on the plane of the substrate 100 (FIG. 1 only shows an example of the film layer position relationship of the pixel driving circuit 210 and the light-emitting elements D0, and does not show the orthographic projection position relationship of the pixel driving circuit 210 and the light-emitting elements D0 on the plane of the substrate 100).

The embodiments of the present disclosure provide a DGLD technology, in which at least one data signal line DL may be electrically connected to the sub-pixels P in two pixel columns. Sub-pixels P located in a same pixel row and connected to a same data signal line DL are connected to different scanning signal lines (not shown in FIG. 2), respectively. This allows the same data signal lines DL electrically connected to the sub-pixels P in the two pixel columns to provide data signals to the sub-pixels P in the two pixel columns in a time-division manner. In this manner, a number of data signal lines DL in the display area AA is less than a number of pixel columns, facilitating reducing the number of signal lines in the display area AA, thereby reducing the interference of signal lines in the display area AA on the alignment abnormality detection of the color-filter structure 310. It should be noted that FIG. 2 only shows that two pixel columns electrically connected to the same data signal line DL are arranged adjacently, and the two pixel columns are located on opposite sides of the same data signal line DL. In one or more other embodiments, the two pixel columns electrically connected to the same data signal line DL may not be arranged adjacently, and/or the two pixel columns may be located on a same side of the same data signal line DL.

With continued reference to FIGS. 1 and 2, the array substrate 001 further includes multiple first light-shielding lines OL1 located on a side of the color-filter layer 300 facing the substrate 100, arranged along a first direction X and extending along a second direction Y. Orthographic projections of the data signal lines DL on the plane of the substrate 100 overlap orthographic projections of the first light-shielding lines OL1 on the plane of the substrate 100. The color-filter layer 300 is located in a display area AA. The color-filter layer 300 includes multiple color-filter structures 310. An orthographic projection of a color-filter structure 310 on the plane of the substrate 100 overlap orthographic projections of the sub-pixels P on the plane of the substrate 100. The color-filter structure 310 includes a first edge S1 and a second edge S2 arranged opposite to each other along the first direction X. An orthographic projection of the first edge S1 and an orthographic projection of the second edge S2 on the plane of the substrate 100 overlap orthographic projections of the first light-shielding lines OL1 on the plane of the substrate 100.

The first light-shielding lines OL1 include an opaque material so that the light transmittance of the first light-shielding lines OL1 is low. The first light-shielding lines OL1 may be a conductive material or an insulating material, and may include an organic material or an inorganic material, and the material of the first light-shielding lines OL1 is not limited in the embodiments of the present disclosure. The first light-shielding lines OL1 may be located at any position between the substrate 100 and the color-filter layer 300, and the film layer position where the first light-shielding lines OL1 are located is not limited in the embodiments of the present disclosure. In an embodiment, the first light-shielding lines OL1 in the array substrate 001 may be disposed in a same layer, and in one or more other embodiments, the first light-shielding lines OL1 in the array substrate 001 may also be disposed in different film layer positions. For example, a bottom light-shielding structure (not shown in FIGS. 1 and 2) is provided on a side of the pixel driving circuit 210 facing the substrate 100 to shield light incident from the substrate 100 toward a channel region of the thin-film transistor. The first light-shielding lines OL1 and the bottom light-shielding structure may be disposed in a same layer, and the first light-shielding lines OL1 are also located on the side of the pixel driving circuit 210 facing the substrate 100. In this case, both the bottom light-shielding structure and the first light-shielding lines OL1 may include a metal light-shielding material.

In one or more embodiments, an orthographic projection of each data signal line DL on the plane of the substrate 100 overlaps orthographic projections of the first light-shielding lines OL1 on the plane of the substrate 100, and orthographic projections of part of the first light-shielding lines OL1 on the plane of the substrate 100 do not overlap orthographic projections of the data signal lines DL on the plane of the substrate 100. In an embodiment, the number of data signal lines DL is less than or equal to the number of first light-shielding lines OL1, ensuring that orthographic projections of all data signal lines DL on the plane of the substrate 100 overlap orthographic projections of the first light-shielding lines OL1 on the plane of the substrate 100, thus avoiding interference of the data signal lines DL on the alignment abnormality detection of the color-filter structure 310. In one or more other embodiments, along the first direction X, lengths of the data signal lines DL are smaller than or equal to lengths of the first light-shielding lines OL1, thus avoiding the influence of the larger size of the data signal line DL along the first direction X on the alignment abnormality detection of the color-filter structure 310.

The color-filter layer 300 includes color-filter structures 310 of various colors. For example, the color-filter structures 310 may include a red color-filter structure 311, a green color-filter structure 312 and a blue color-filter structure 313. It should be noted that FIGS. 1 and 2 only show an example of the red color-filter structure 311, the green color-filter structure 312 and the blue color-filter structure 313 arranged sequentially along the first direction X, but it is not limited thereto. An orthographic projection of the color-filter structure 310 on the plane of the substrate 100 covers orthographic projections of the light-emitting elements D0 of the sub-pixels P on the plane of the substrate 100. Light of corresponding colors passes through the color-filter structures 310 so that different sub-pixels P present different colors.

The first edge S1 and the second edge S2 of the color-filter structure 310 are arranged along the first direction X and extend along the second direction Y. In an embodiment, the orthographic projection of the first edge S1 and the orthographic projection of the second edge S2 on the plane of the substrate 100 are both located within the contour (including the contour edges) of orthographic projections of the first light-shielding lines OL1 on the plane of the substrate 100. The orthographic projection of the first edge S1 of the same color-filter structure 310 and the orthographic projection of the second edge S2 of the same color-filter structure 310 on the plane of the substrate 100 are located within the contour (including the contour edges) of orthographic projections of different first light-shielding lines OL1 on the plane of the substrate 100, respectively. In one or more other embodiments, orthographic projections of the first light-shielding lines OL1 on the plane of the substrate 100 may be used as a configuration area where the pixel columns are divided. In other words, along the first direction X, the first light-shielding lines OL1 may be provided on the opposite sides of each pixel column, so that the orthographic projection of the first edge S1 and the orthographic projection of the second edge S2 of the color-filter structure 310 on the plane of the substrate 100 can be located within the contour (including the contour edges) of orthographic projections of the first light-shielding lines OL1 on the plane of the substrate 100.

Specifically, multiple first light-shielding lines OL1 are arranged on the side of the color-filter layer 300 facing the substrate 100, so that whether an alignment abnormality of the color-filter structure 310 exists can be detected by using the first light-shielding lines OL1 as references. The orthographic projection of the first edge S1 and the orthographic projection of the second edge S2 on the plane of the substrate 100 are configured to overlap orthographic projections of the first light-shielding lines OL1 on the plane of the substrate 100, and this allows for the determination of alignment abnormality of the color-filter structure 310 when the orthographic projection of the first edge S1 or the orthographic projection of the second edge S2 on the plane of the substrate 100 does not overlap orthographic projections of the first light-shielding lines OL1 on the plane of the substrate 100. Therefore, when the alignment abnormality detection of the color-filter structure 310 is performed, the first light-shielding lines OL1 do not need to be used as references to accurately measure the distance between the edge of the color-filter structure 310 and the first light-shielding lines OL1 along the first direction X, and accurate focus in the detection process is not required, simplifying the color-filter structure detection method and improving detection efficiency and accuracy.

Moreover, combining DGLD technology, at least one data signal line DL may be electrically connected to the sub-pixels P in two pixel columns, reducing the number of data signal lines DL in the display area AA, thus reducing the conductive lines in the display area AA. This facilitates reducing the interference of the conductive lines in the display area AA on the alignment abnormality detection of the color-filter structure 310, and can further improve the situation where the short distance between the two conductive lines causes ghosting and blurring of the detection image.

Furthermore, orthographic projections of the data signal lines DL on the plane of the substrate 100 overlap orthographic projections of the first light-shielding lines OL1 on the plane of the substrate 100, so that orthographic projections of the data signal lines DL on the plane of the substrate 100 are also located at orthographic projection positions of the first edge S1 or the second edge S2 of the color-filter structure 310. In one aspect, this avoids a situation in which, when orthographic projections of the data signal lines DL on the plane of the substrate 100 are close to orthographic projections of the first light-shielding lines OL1 on the plane of the substrate 100, ghosting and blurring of the detection image occur. In another aspect, this avoids a situation in which, when orthographic projections of the data signal lines DL on the plane of the substrate 100 are far from orthographic projections of the first light-shielding lines OL1 on the plane of the substrate 100, the data signal line DL is mistakenly recognized as a first light-shielding line OL1 during detection, thereby causing misjudgment of alignment abnormality detection of the color-filter structure 310.

In an example, when alignment abnormality detection of the color-filter structure 310 is performed, the display area AA of the array substrate 001 may be captured to acquire a detection image by using a visual inspection system, and the detection image may be automatically recognized by using an automated optical inspection (AOI) technology. In an embodiment, a light source may be provided on a side of the substrate 100 facing away from the color-filter layer 300, as shown in FIG. 1. Light from the light source passes through the substrate 100, the light-emitting functional layer 200, and the color-filter layer 300 sequentially. The array substrate 001 is captured at a side of the color-filter layer 300 facing away from the substrate 100 to acquire the detection image.

Along the first direction X, if a color-filter structure 310 exists in part of a region between two adjacent first light-shielding lines OL1 and no color-filter structure 310 exists in another part of the region, that is, along the first direction X, if the region between two adjacent first light-shielding lines OL1 exhibits both a color of the color-filter structure 310 and a color of the light source (usually white light), this may be caused by an abnormally small size of part of the color-filter structure 310 along the first direction X, such that the color-filter structure 310 does not completely cover a sub-pixel configuration area between the two adjacent first light-shielding lines OL1. Alternatively, this may be caused by an abnormally large size of part of the color-filter structure 310 along the first direction X, such that the color-filter structure 310 extends into other sub-pixel configuration areas arranged along the first direction X, and the first edge S1 and/or the second edge S2 is not located within the contour of the first light-shielding lines OL1. In this case, it should be determined that an alignment abnormality of the color-filter structure 310 exists.

If a contour of the first light-shielding lines OL1 is different from a contour of the first light-shielding lines OL1 immediately after fabrication, for example, when the contour of the first light-shielding lines OL1 is straight immediately after fabrication and changes after the color-filter structure 310 is formed, an abnormal protrusion along the first direction X may exist in a local area of the first light-shielding lines OL1. The abnormal protrusion is an opaque black area, which may be caused by an abnormally large size of part of the color-filter structure 310 along the first direction X. The opaque black area is formed because an orthographic projection of the color-filter structure 310 on the plane of the substrate 100 overlaps orthographic projections of multiple sub-pixels P arranged along the first direction X on the plane of the substrate 100, and overlaps a color-filter structure 310 in other sub-pixel configuration areas. In this case, the first edge S1 and/or the second edge S2 is not located within the contour of the first light-shielding lines OL1, and it should also be determined that an alignment abnormality of the color-filter structure 310 exists.

According to the array substrate provided by the embodiments of the present disclosure, at least one data signal line is electrically connected to sub-pixels in two pixel columns by using DGLD technology, thereby reducing the number of conductive lines in the display area and facilitating reduction of interference of conductive lines on alignment abnormality detection of a color-filter structure, and further improving a situation in which a short distance between two conductive lines causes ghosting and blurring of a detection image. Multiple first light-shielding lines are arranged along the first direction and extend along the second direction on a side of the color-filter layer facing the substrate, so that alignment abnormality detection of the color-filter structure can be performed by using the first light-shielding lines as references. Orthographic projections of the data signal lines on the plane of the substrate overlap orthographic projections of the first light-shielding lines on the plane of the substrate, facilitating improvement of detection accuracy and avoiding misjudgment of alignment abnormality detection of the color-filter structure caused by the data signal lines. Furthermore, orthographic projections of the first edge and the second edge of the color-filter structure on the plane of the substrate are configured to overlap orthographic projections of the first light-shielding lines on the plane of the substrate. Accordingly, when an orthographic projection of the first edge or an orthographic projection of the second edge on the plane of the substrate does not overlap orthographic projections of the first light-shielding lines on the plane of the substrate, an alignment abnormality of the color-filter structure can be determined. Therefore, when alignment abnormality detection of the color-filter structure is performed, only whether an abnormal protrusion along the first direction exists in a contour of orthographic projections of the first light-shielding lines on the plane of the substrate, or whether a gap exists between an orthographic projection of the first edge or the second edge on the plane of the substrate and orthographic projections of the first light-shielding lines on the plane of the substrate needs to be determined. Accurate detection of the color-filter structure in the display area can thus be achieved without accurately measuring a distance between an edge of the color-filter structure and the first light-shielding lines along the first direction and without accurate focusing during detection, thereby simplifying the color-filter structure detection method and improving detection efficiency and detection accuracy.

It should be noted that the array substrate provided by the embodiments of the present disclosure may be an intermediate product in the fabrication process; for example, it may be an array substrate in which only part of the color-filter structures 310 have been fabricated. Alternatively, the array substrate provided by the embodiments of the present disclosure may also be a semi-finished product or a finished product in the fabrication process; for example, it may be an array substrate in which all the color-filter structures 310 have been fabricated and surface processing of the color-filter structures 310 has been completed. The embodiments of the present disclosure do not limit the completion degree of the array substrate.

In one or more embodiments, with continued reference to FIG. 2, along the first direction X, adjacent color-filter structures 310 have different colors.

Specifically, when the array substrate emits light, adjacent sub-pixels P arranged along the first direction X exhibit different colors. A first light-shielding line OL1 is provided between sub-pixels P with different colors arranged along the first direction X, and the first light-shielding line OL1 is used to detect whether the color-filter structure 310 located on a light-emitting side of the sub-pixels P has a positional deviation along the first direction X.

In an example, referring to FIG. 2, the color-filter structure 310 includes the red color-filter structure 311, the green color-filter structure 312 and the blue color-filter structure 313. Along the first direction X, adjacent color-filter structures 310 have different colors. When the position of the color-filter structure 310 deviates along the first direction X, whether a position of the first edge S1 and/or a position of the second edge S2 of the color-filter structure 310 deviates can be quickly detected by detecting a gap between the color-filter structure 310 and the first light-shielding line OL1 in the detection image, or by detecting an abnormal black protrusion in a contour of the first light-shielding line OL1.

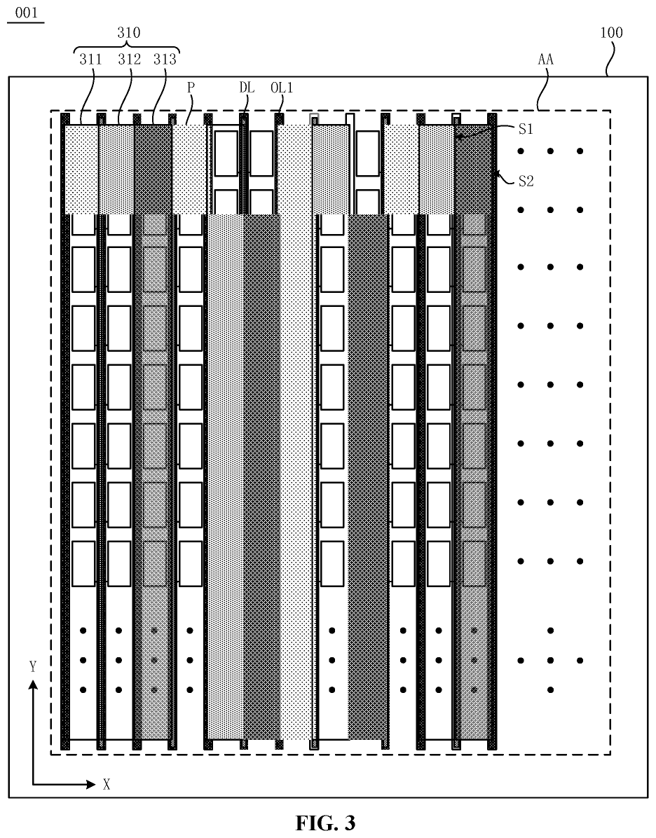

In one or more embodiments, FIG. 3 is another schematic top view of an array substrate according to an embodiment of the present disclosure. An orthographic projection of the same color-filter structure 310 on the plane of the substrate 100 covers orthographic projections of multiple sub-pixels P arranged along the second direction Y on the plane of the substrate 100.

In an example, adjacent color-filter structures 310 arranged along the first direction X have different colors, and adjacent color-filter structures 310 arranged along the second direction Y have the same color. In this case, a size of the color-filter structure 310 in the second direction may be increased, so that an orthographic projection of the color-filter structure 310 on the plane of the substrate 100 can cover orthographic projections of multiple sub-pixels P arranged along the second direction Y on the plane of the substrate 100. In this manner, color-filter structures 310 of the same color arranged along the second direction Y may be configured as an integrated structure, reducing the process difficulty, especially reducing the fabrication difficulty of the color-filter layer 300 of the high-resolution array substrate 001, thereby facilitating simplifying the fabrication process and improving the product yield.

On the basis of the above embodiments, referring to FIGS. 2 and 3, along the second direction Y, a length of a first light-shielding line OL1 is greater than a length of a color-filter structure 310.

In an example, when adjacent color-filter structures 310 arranged along the first direction X overlap each other and a large overlapping area causes an abnormal protrusion along the first direction X in a contour of the first light-shielding line OL1 in the detection image, a length of the first light-shielding line OL1 along the second direction Y may be greater than a length of the abnormal protrusion along the second direction Y. In this manner, when the abnormal protrusion exists in the contour of the first light-shielding line OL1 in the detection image, the visual inspection system can quickly detect the misalignment based on the fact that a size of the abnormal protrusion in the first direction X is larger than a size of other parts of the first light-shielding line OL1 in the first direction X, thus facilitating improving the detection efficiency and accuracy.

In one or more embodiments, with continued reference to FIGS. 2 and 3, an orthographic projection of the color-filter structure 310 on the plane of the substrate 100 only overlaps orthographic projections of two adjacent first light-shielding lines OL1 arranged along the first direction X on the plane of the substrate 100.

Specifically, an orthographic projection of the same color-filter structure 310 on the plane of the substrate 100 only overlaps orthographic projections of two adjacent first light-shielding lines OL1 arranged along the first direction X on the plane of the substrate 100, and does not overlap an orthographic projection of a third first light-shielding line OL1 on the plane of the substrate 100, thus preventing an excessive number of first light-shielding lines OL1 from interfering with the alignment abnormality detection of the color-filter structure 310.

On the basis of the above embodiments, orthographic projections of the first light-shielding lines OL1 on the plane of the substrate 100 overlap an orthographic projection of the first edge S1 and/or an orthographic projection of the second edge S2 on the plane of the substrate 100. In an embodiment, orthographic projections of all the first light-shielding lines OL1 on the plane of the substrate 100 overlap an orthographic projection of the first edge S1 and/or an orthographic projection of the second edge S2 of the color-filter structure 310 on the plane of the substrate 100. No case occurs in which an orthographic projection of a first light-shielding line OL1 on the plane of the substrate 100 overlaps neither an orthographic projection of the first edge S1 on the plane of the substrate 100 nor an orthographic projection of the second edge S2 on the plane of the substrate 100.

In another alternative embodiment, with continued reference to FIGS. 2 and 3, an orthographic projection of only one first light-shielding line OL1 on the plane of the substrate 100 exists between orthographic projections of two adjacent pixel columns arranged along the first direction X on the plane of the substrate 100. In other words, an orthographic projection of only one pixel column on the plane of the substrate 100 exists between orthographic projections of two adjacent first light-shielding lines OL1 arranged along the first direction X on the plane of the substrate 100.

In an example, orthographic projections of any two adjacent first light-shielding lines OL1 arranged along the first direction X on the plane of the substrate 100 define a region where a pixel column is located. Only one pixel column is configured in the region between any two adjacent first light-shielding lines OL1 arranged along the first direction X. In other words, the region between any two adjacent first light-shielding lines OL1 arranged along the first direction X is configured with a pixel column and is configured with only one pixel column. No orthographic projections of two first light-shielding lines OL1 on the plane of the substrate 100 are located between orthographic projections of two adjacent pixel columns arranged along the first direction X on the plane of the substrate 100. This facilitates detecting misalignment of the color-filter structure 310, and avoids ghosting and blurring caused by the presence of multiple first light-shielding lines OL1 in a region between two adjacent sub-pixels P arranged along the first direction X, thereby avoiding interference in detection.

On this basis, an orthographic projection of the color-filter structure 310 on the plane of the substrate 100 only overlaps orthographic projections of sub-pixels P in one pixel column defined by the region between adjacent first light-shielding lines OL1, and does not overlap orthographic projections of sub-pixels P in two pixel columns on the plane of the substrate 100. This ensures that adjacent sub-pixels P arranged along the first direction X are not covered by the same color-filter structure 310. Therefore, adjacent sub-pixels P arranged along the first direction X can present different colors during display, facilitating improving the display effect.

As described above, alignment abnormality detection of the color-filter structure 310 is implemented through multiple first light-shielding lines OL1 arranged along the first direction X and extending along the second direction Y. Orthographic projections of multiple data signal lines DL arranged along the first direction X and extending along the second direction Y on the plane of the substrate 100 need to overlap orthographic projections of the first light-shielding lines OL1 on the plane of the substrate 100 to prevent the data signal lines DL from interfering with alignment abnormality detection of the color-filter structure 310. However, the display area AA of the array substrate 001 is not only provided with data signal lines DL. In addition to the data signal lines DL, the display area AA is provided with other signal lines. These other signal lines may also interfere with alignment abnormality detection of the color-filter structure 310, especially other signal lines arranged along the first direction X and extending along the second direction Y. Therefore, the embodiments of the present disclosure provide various implementations to improve a situation where other signal lines may interfere with alignment abnormality detection of the color-filter structure 310.

In an embodiment, only the data signal line DL is arranged along the first direction X and extends along the second direction Y, and other signal lines may be arranged along the second direction Y and extend along the first direction X. For example, scanning signal lines, power signal lines and reference signal lines may extend along the first direction X (not shown in FIGS. 1 to 3). In this manner, the number of signal lines extending along the second direction Y can be reduced, thus preventing an excessive number of signal lines extending along the second direction Y from interfering with the alignment abnormality detection of the color-filter structure 310.

In one or more other embodiments, orthographic projections of other signal lines arranged along the first direction X and extending along the second direction Y on the plane of the substrate 100 may also be configured to overlap orthographic projections of the first light-shielding lines OL1 on the plane of the substrate 100. In an example, the display area AA is also provided with power signal lines and/or reference signal lines arranged along the first direction X and extending along the second direction Y. Orthographic projections of the power signal lines and/or orthographic projections of the reference signal lines on the plane of the substrate 100 overlap orthographic projections of the first light-shielding lines OL1 on the plane of the substrate 100 (not shown in FIGS. 1 to 3), thus reducing the interference of the power signal lines and/or reference signal lines on the alignment abnormality detection of the color-filter structure 310. On this basis, at least one of the power signal lines and/or at least one of the reference signal lines may be electrically connected to sub-pixels P in multiple pixel columns, thus reducing the number of power signal lines and/or the number of reference signal lines in the display area AA, further reducing interference and improving detection efficiency and accuracy.

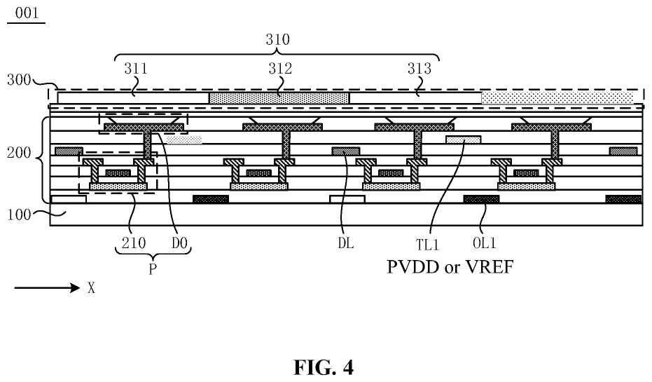

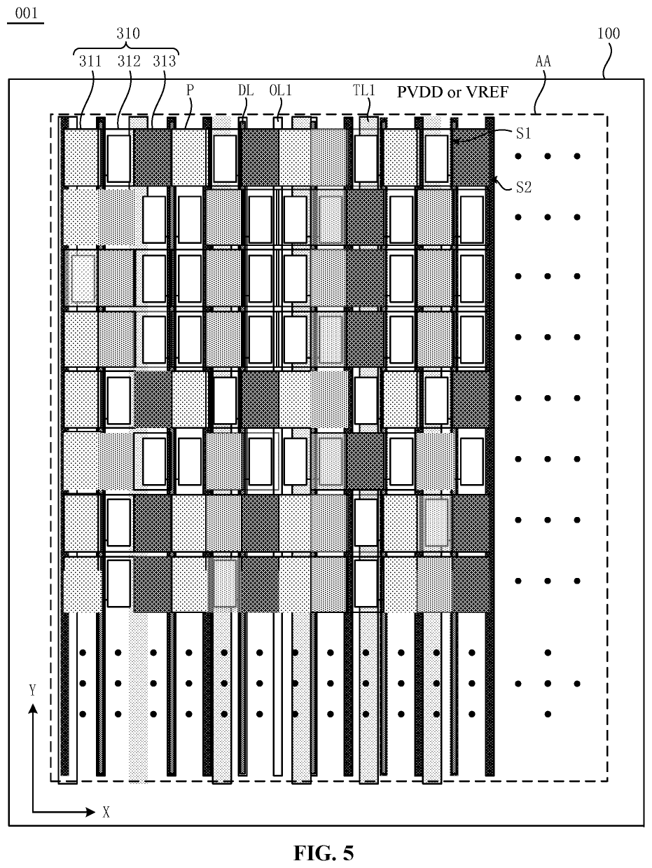

In one or more other embodiments, at least one of the signal lines extending along the second direction Y, excluding the data signal lines DL, may also be configured to include a transparent conductive material. FIG. 4 is another schematic diagram of a film layer structure of an array substrate according to an embodiment of the present disclosure, and FIG. 5 is another schematic top view of an array substrate according to an embodiment of the present disclosure. Referring to FIGS. 4 and 5, the light-emitting functional layer 200 further includes multiple first signal lines TL1 arranged along the first direction X and extending along the second direction Y, and the first signal lines TL1 include the transparent conductive material.

The first signal lines TL1 include, but are not limited to, power signal lines PVDD, reset signal lines VREF, and other signal lines.

Specifically, the first signal lines TL1 include the transparent conductive material, and transparent first signal lines TL1 have little impact on the detection image and hardly interfere with the alignment abnormality detection of the color-filter structure 310 by the visual inspection system. The first signal lines TL1 arranged along the first direction X and extending along the second direction Y include the transparent conductive material, thus reducing the interference of the first signal lines TL1 extending along the second direction Y on the alignment abnormality detection of the color-filter structure 310.

It can be understood that the first signal lines TL1 are transparent conductive lines, have good light transmittance, and hardly interfere with the alignment abnormality detection of the color-filter structure 310. Therefore, orthographic projections of the first signal lines TL1 on the plane of the substrate 100 may or may not overlap orthographic projections of the first light-shielding lines OL1 on the plane of the substrate 100, and positions of the first signal lines TL1 are not limited in the embodiments of the present disclosure.

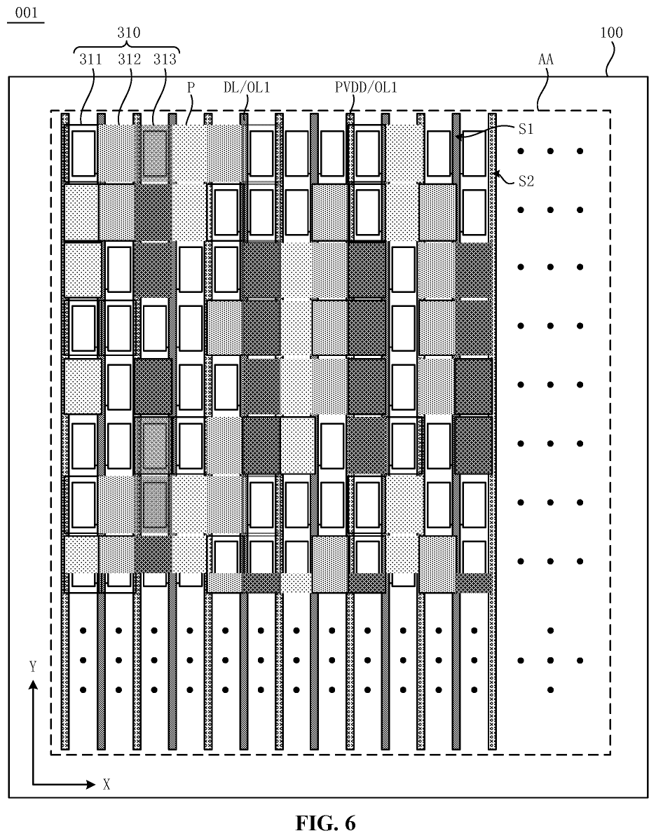

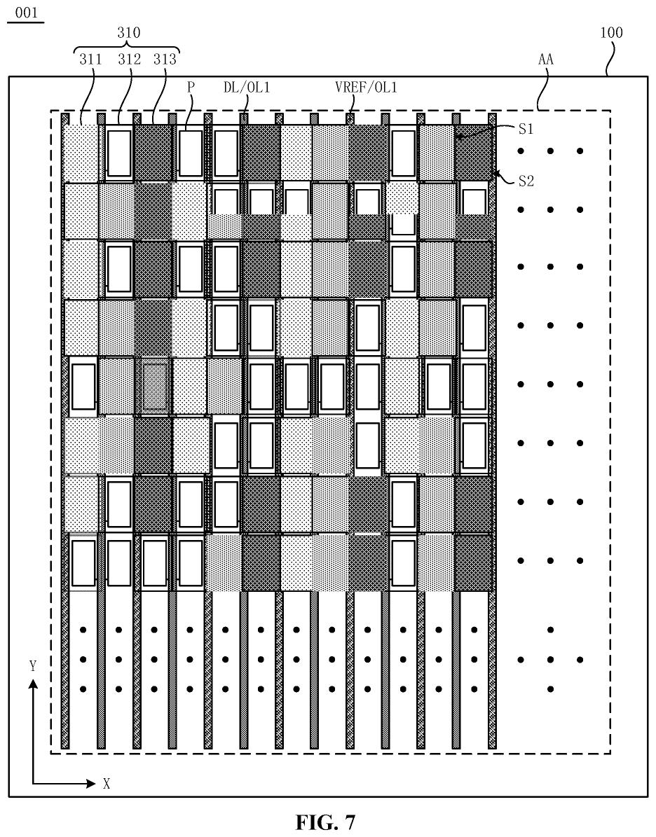

In one or more embodiments, FIG. 6 is another schematic top view of an array substrate according to an embodiment of the present disclosure, and FIG. 7 is another schematic top view of an array substrate according to an embodiment of the present disclosure. Referring to FIGS. 6 and 7, the data signal lines DL also serve as the first light-shielding lines OL1.

In an example, a case where all data signal lines DL are electrically connected to the sub-pixels P in two pixel columns, and orthographic projections of the two pixel columns electrically connected to the same data signal line DL on the plane of the substrate 100 are respectively located on opposite sides of an orthographic projection of the same data signal line DL on the plane of the substrate 100 is taken as an example. Referring to FIGS. 6 and 7, an i-th data signal line DL arranged along the first direction X may be electrically connected to the sub-pixels P in a (2×i−1)-th pixel column and the sub-pixels P in a (2×i)-th pixel column, and an orthographic projection of the i-th data signal line DL arranged along the first direction X on the plane of the substrate 100 is located between an orthographic projection of the (2×i−1)-th pixel column and an orthographic projection of the (2×i)-th pixel column on the plane of the substrate 100. An orthographic projection of a (2×i)-th first light-shielding line OL1 arranged along the first direction X on the plane of the substrate 100 is also located between the orthographic projection of the (2×i−1)-th pixel column and the orthographic projection of the (2×i)-th pixel column on the plane of the substrate 100. The (2×i)-th first light-shielding line OL1 arranged along the first direction X may also be configured to serve as a data signal line DL, and i is a positive integer. The data signal lines DL also serve as the first light-shielding lines OL1, facilitating reducing the number of signal lines in the display area AA, thereby reducing the number of film layers, simplifying the process and lowering the fabrication cost.

It can be understood that in other embodiments, orthographic projections of two pixel columns electrically connected to the same data signal line DL on the plane of the substrate 100 may also be located on a same side of an orthographic projection of the same data signal line DL on the plane of the substrate 100. For example, the i-th data signal line DL arranged along the first direction X may be electrically connected to the sub-pixels P in the (2×i−1)-th pixel column and the sub-pixels P in the (2×i)-th pixel column. An orthographic projection of the i-th data signal line DL arranged along the first direction X on the plane of the substrate 100 may be located between an orthographic projection of a (2×i−1+m)-th pixel column and an orthographic projection of a (2×i+m)-th pixel column on the plane of the substrate 100. In this case, a (2×i+m)-th first light-shielding line OL1 arranged along the first direction X may also be configured to serve as a data signal line DL, where i is a positive integer, and m is a non-zero integer.

In one or more other embodiments, two pixel columns electrically connected to the same data signal line DL may not be adjacent. For example, the i-th data signal line DL arranged along the first direction X may be electrically connected to the sub-pixels P in a (2×i−1+r)-th pixel column and the sub-pixels P in a (2×i+k)-th pixel column. An orthographic projection of the i-th data signal line DL arranged along the first direction X on the plane of the substrate 100 may be located between an orthographic projection of a (2×i−1+n)-th pixel column and an orthographic projection of a (2×i+n)-th pixel column on the plane of the substrate 100. In this case, a (2×i+n)-th first light-shielding line OL1 along the first direction X may also be configured to reuse a data signal line DL, where r and k are different integers, and n is an integer.

It should be noted that different filling patterns of the first light-shielding line OL1 that reuses the data signal line DL and the first light-shielding line OL1 that does not reuse the data signal line DL in FIGS. 6 and 7 are only to represent different structures, and are not intended to limit a difference in film layer position and/or a difference in material. In an embodiment, the first light-shielding line OL1 that does not reuse the data signal line DL and the data signal line DL may be disposed in different film layers. In other words, the first light-shielding line OL1 that does not reuse the data signal line DL and the first light-shielding line OL1 that reuses the data signal line DL may be disposed in different film layers. Alternatively, the first light-shielding line OL1 that does not reuse the data signal line DL and the data signal line DL may be disposed in a same film layer and may be formed in a same process. In an embodiment, the first light-shielding line OL1 that does not reuse the data signal line DL and the data signal line DL may be disposed in the same film layer, but is not electrically connected to the sub-pixels P.

As described above, at least one of the data signal lines DL is electrically connected to the sub-pixels P in two pixel columns, and the number of data signal lines DL is less than the number of pixel columns. Along the first direction X, first light-shielding lines OL1 are provided at two opposite sides of each pixel column. Moreover, a first light-shielding line OL1 is provided in a region between two adjacent pixel columns. Since the number of first light-shielding lines OL1 is greater than the number of pixel columns, the number of first light-shielding lines OL1 is greater than the number of data signal lines DL. In an embodiment, all the data signal lines DL also serve as the first light-shielding lines OL1. In other words, part of the first light-shielding lines OL1 may reuse the data signal lines DL, and part of the first light-shielding lines OL1 may not reuse the data signal lines DL. The first light-shielding lines OL1 that do not reuse the data signal lines DL may not reuse any signal lines, or may reuse other signal lines extending along the second direction Y other than the data signal lines DL.

In one or more embodiments, with continued reference to FIGS. 6 and 7, the array substrate 001 further includes power signal lines PVDD and reset signal lines VREF. The power signal lines PVDD also serve as the first light-shielding lines OL1, and/or the reset signal lines VREF also serve as the first light-shielding lines OL1.

In an embodiment, the first light-shielding lines OL1 reuse the data signal lines DL and the power signal lines PVDD. In other words, the data signal lines DL and the power signal lines PVDD in the array substrate 001 also serve as the first light-shielding lines OL1, as shown in FIG. 6. In this case, the reset signal lines VREF may be configured to extend along the first direction X or may be configured as transparent conductive lines (not shown in FIG. 6). In one or more other embodiments, the first light-shielding lines OL1 also reuse the data signal lines DL and the reset signal lines VREF. In other words, the data signal lines DL and the reset signal lines VREF in the array substrate 001 also serve as the first light-shielding lines OL1, as shown in FIG. 7. In this case, the power signal lines PVDD may be configured to extend along the first direction X or may be configured as transparent conductive lines (not shown in FIG. 7). Since the power signal lines PVDD and/or the reset signal lines VREF also serve as the first light-shielding lines OL1, the first light-shielding lines OL1 that do not reuse the data signal lines DL can reuse the power signal lines PVDD and/or the reset signal lines VREF. In this manner, the first light-shielding lines OL1 do not need to be fabricated separately, facilitating simplifying the process, thereby reducing the number of film layers and lowering the fabrication cost.

It can be understood that different filling patterns of the data signal lines DL that also serve as the first light-shielding lines OL1 and the power signal lines PVDD that also serve as the first light-shielding lines OL1 in FIG. 6 are only to represent different structures, and are not intended to limit a difference in film layer position and/or a difference in material. In FIG. 7, different filling patterns of the data signal lines DL that also serve as the first light-shielding lines OL1 and the reset signal lines VREF that also serve as the first light-shielding lines OL1 are only to represent different structures, and are not intended to limit a difference in film layer position and/or a difference in material.

On the basis of the above embodiments, with continued reference to FIGS. 6 and 7, along the first direction X, a power signal line PVDD is located between two adjacent data signal lines DL, and/or a reset signal line VREF is located between two adjacent data signal lines DL.

Specifically, along the first direction X, an orthographic projection of a power signal line PVDD that also serves as the first light-shielding line OL1 on the plane of the substrate 100 is located between orthographic projections of two adjacent data signal lines DL on the plane of the substrate 100, and/or an orthographic projection of a reset signal line VREF that also serves as the first light-shielding line OL1 on the plane of the substrate 100 is located between orthographic projections of two adjacent data signal lines DL on the plane of the substrate 100.

In an example, along the first direction X, the (2×i)-th first light-shielding line OL1reuses the data signal line DL. In this case, the (2×i−1)-th first light-shielding line OL1 may reuse the power signal line PVDD or the reset signal line VREF. As shown in FIGS. 6 and 7, multiple first light-shielding lines OL1 arranged sequentially along the first direction X may be PVDD-DL-PVDD-DL- . . . or VREF-DL-VREF-DL- . . . . Alternatively, along the first direction X, the (2×i−1)-th first light-shielding line OL1 reuses the data signal line DL. In this case, the (2×i)-th first light-shielding line OL1 may reuse the power signal line PVDD or the reset signal line VREF, and multiple first light-shielding lines OL1 arranged sequentially along the first direction X may be DL-PVDD-DL-PVDD- . . . or DL-VREF-DL-VREF- . . . , where i is a positive integer.

On the basis of the above embodiments, FIG. 8 is another schematic top view of an array substrate according to an embodiment of the present disclosure. When both the power signal lines PVDD and the reset signal lines VREF also serve as the first light-shielding lines OL1, the power signal lines PVDD and the reset signal lines VREF are alternately arranged along the first direction X.

In an example, along the first direction X, the (2×i)-th first light-shielding line OL1 reuses the data signal line DL. In this case, the (2×i−1)-th first light-shielding line OL1 reuses the power signal line PVDD, and the (2×i+1)-th first light-shielding line OL1 reuses the reset signal line VREF. As shown in FIG. 8, multiple first light-shielding lines OL1 arranged sequentially along the first direction X may be PVDD-DL-VREF-DL-PVDD-DL-VREF-DL- . . . . Alternatively, the (2×i)-th first light-shielding line OL1 reuses the data signal line DL. In this case, the (2×i−1)-th first light-shielding line OL1 reuses the reset signal line VREF, and the (2×i+1)-th first light-shielding line OL1 reuses the power signal line PVDD, and multiple first light-shielding lines OL1 arranged sequentially along the first direction X may also be VREF-DL-PVDD-DL-VREF-DL-PVDD-DL- . . . .

In one or more other embodiments, along the first direction X, the (2×i−1)-th first light-shielding line OL1 reuses the data signal line DL. In this case, multiple first light-shielding lines OL1 sequentially arranged along the first direction X may be DL-PVDD-DL-VREF-DL-PVDD-DL-VREF- . . . or DL-VREF-DL-PVDD-DL-VREF-DL-PVDD . . . .

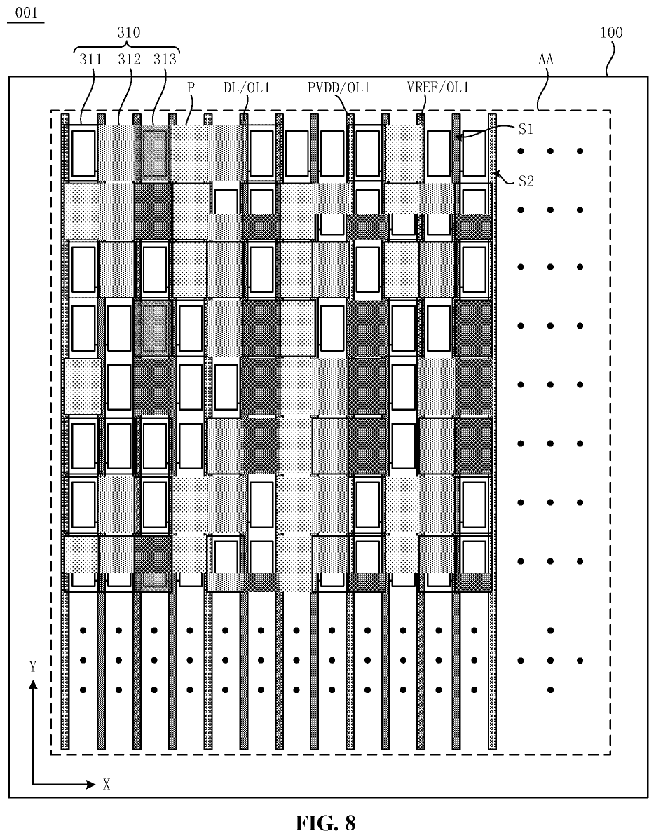

In one or more embodiments, FIG. 9 is another schematic top view of an array substrate according to an embodiment of the present disclosure. Referring to FIG. 9, the array substrate 001 includes multiple pixel units PU arranged in an array in the display area AA. The pixel units PU include a first-color sub-pixel P01, a second-color sub-pixel P02, a third-color sub-pixel P03 and a fourth-color sub-pixel P04 arranged along the first direction X. Within a same pixel unit PU, one of the data signal lines DL is disposed between the first-color sub-pixel P01 and the second-color sub-pixel P02, and another one of the data signal lines DL is disposed between the third-color sub-pixel P03 and the fourth-color sub-pixel P04.

The embodiments of the present disclosure do not limit the first-color, the second-color, the third-color and the fourth-color. In an embodiment, the first-color, the second-color, the third-color and the fourth-color may all be different colors. In other words, any two colors are different. In one or more other embodiments, the first-color, the second-color, the third-color and the fourth-color may include a same color. For example, the pixel units PU may include R sub-pixels, G sub-pixels, B sub-pixels and G sub-pixels. In one or more other embodiments, the first-color, the second-color, the third-color and the fourth-color may include white. For example, the pixel units PU may include R sub-pixels, G sub-pixels, B sub-pixels and W sub-pixels, and the fourth-color is white. The color-filter structure 310 above the fourth-color sub-pixel P04 needs to be able to transmit white light, and the color-filter structure 310 may not be provided above the fourth-color sub-pixel P04. Alternatively, after the color-filter structures 310 for all other colors are fabricated, when a planarization layer is fabricated on the side of the color-filter layer 300 facing away from the substrate 100, part of the planarization layer can fill a recessed area above the fourth-color sub-pixel P04 as a white color-filter structure.

In an example, one of the data signal lines DL located between the first-color sub-pixel P01 and the second-color sub-pixel P02 is electrically connected to the first-color sub-pixel P01 and the second-color sub-pixel P02 adjacent to the data signal line DL, and another one of the data signal lines DL located between the third-color sub-pixel P03 and the fourth-color sub-pixel P04 is electrically connected to the third-color sub-pixel P03 and the fourth-color sub-pixel P04 adjacent to the other data signal line DL. By disposing one of the data signal lines DL between the first-color sub-pixel P01 and the second-color sub-pixel P02 and disposing another one of the data signal lines DL between the third-color sub-pixel P03 and the fourth-color sub-pixel P04, a distance between each sub-pixel P in the pixel unit PU and a data signal line DL electrically connected to the sub-pixel P is small and equal, facilitating reducing the transmission impedance of the data signal and improving the display uniformity.

With continued reference to FIG. 9, the pixel units PU are arranged in an array. The first-color sub-pixel P01, the second-color sub-pixel P02, the third-color sub-pixel P03 and the fourth-color sub-pixel P04 in the pixel units PU are all arranged sequentially along the first direction X. The sub-pixels P within the same pixel column present the same color during display. In one or more embodiments, a power signal line PVDD or a reset signal line VREF is disposed between the second-color sub-pixel P02 and the third-color sub-pixel P03, and a reset signal line VREF or a power signal line PVDD is disposed between the fourth-color sub-pixel P04 and the first-color sub-pixel P01. In this manner, the distance between the sub-pixels P of the same color and the fixed potential signal line (power signal line PVDD or reset signal line VREF) is the same. In other words, the distance between each sub-pixel P of the same color in the same pixel unit PU and a respective fixed potential signal line (power signal line PVDD or reset signal line VREF) is equal, facilitating improving the display uniformity of different pixel units PU. Furthermore, based on the transmission impedance of the fixed potential signal, the same data signal compensation may be provided to the sub-pixels P of the same color, and different data signal compensation may be provided to at least one of the sub-pixels P of different colors to improve the display deviation between the sub-pixels P of different colors caused by different distances from the fixed potential signal line (power signal line PVDD or reset signal line VREF), thus facilitating accurate display of the image and improving the color reproduction of the image.

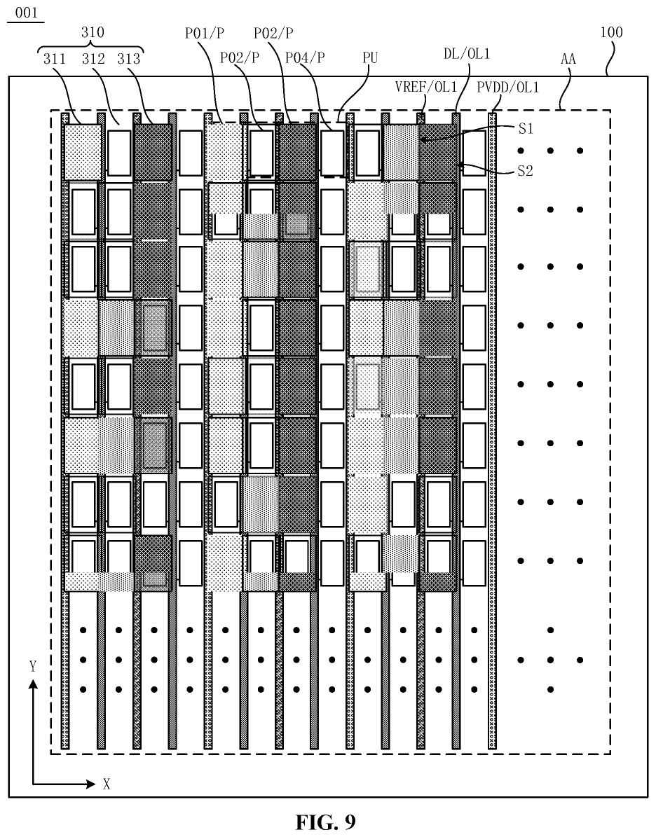

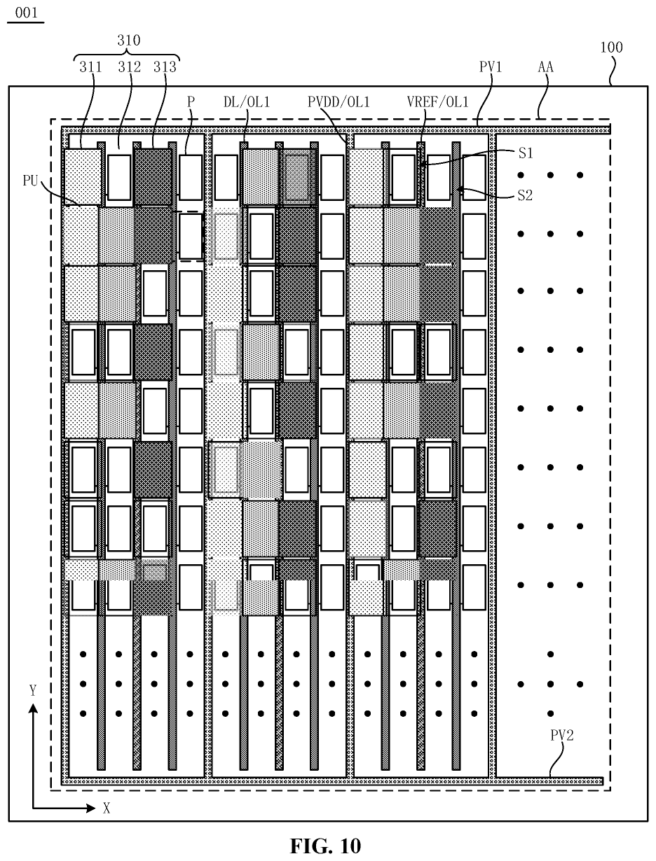

On the basis of the above embodiments, FIG. 10 is another schematic top view of an array substrate according to an embodiment of the present disclosure. Referring to FIG. 10, the pixel units PU include a first-color sub-pixel P01, a second-color sub-pixel P02, a third-color sub-pixel P03 and a fourth-color sub-pixel P04 arranged along the first direction X. One of the data signal lines DL is disposed between the first-color sub-pixel P01 and the second-color sub-pixel P02, and another one of the data signal lines DL is disposed between the third-color sub-pixel P03 and the fourth-color sub-pixel P04. A reset signal line VREF is disposed between the second-color sub-pixel P02 and the third-color sub-pixel P03, and a power signal line PVDD is disposed between the fourth-color sub-pixel P04 and the first-color sub-pixel P01. The array substrate 001 further includes a first auxiliary power supply line PV1 and a second auxiliary power supply line PV2, which are arranged along the second direction Y and extend along the first direction X. The first auxiliary power supply line PV1 and the second auxiliary power supply line PV2 are located on opposite sides of the data signal line DL and the reset signal line VREF. Along the second direction Y, a length of the power signal line PVDD is greater than a length of the reset signal line VREF, and two ends of the power signal line PVDD may be electrically connected to the first auxiliary power supply line PV1 and the second auxiliary power supply line PV2, respectively.

In this manner, the power signal lines PVDD at different positions may be electrically connected to each other through the first auxiliary power supply line PV1 and the second auxiliary power supply line PV2, facilitating reducing the voltage difference between the power signal lines PVDD at different positions, reducing the transmission voltage drop and improving the display uniformity. Furthermore, the power signal lines PVDD located between the pixel units PU are longer in the second direction Y, and are electrically connected to the first auxiliary power supply line PV1 and the second auxiliary power supply line PV2 extending along the first direction X, facilitating feature extraction and positioning during visual recognition. The visual inspection system can quickly recognize the power signal lines PVDD and the pixel units PU located between two adjacent power signal lines PVDD. Therefore, whether the color of the color-filter structure 310 in the configuration area of each sub-pixel P in the pixel units PU is accurate can be quickly determined based on the pixel units PU, thus facilitating improving the detection efficiency and accuracy and avoiding the overall misalignment of the color-filter structure 310, such as avoiding a situation where a red color-filter structure 311 is disposed above a green sub-pixel and fails to be detected in time.

In an embodiment, with continued reference to FIG. 10, the power signal lines PVDD, the first auxiliary power line PV1 and the second auxiliary power line PV2 may be disposed in a same layer and may be an integrated structure. On this basis, the data signal lines DL and the reset signal lines VREF that also serve as the first light-shielding lines OL1 may be disposed in different film layers from the power signal lines PVDD. Alternatively, the data signal lines DL and the reset signal lines VREF that also serve as the first light-shielding lines OL1 may also be disposed in the same film layer as the power signal lines PVDD. To avoid short-circuit with the power signal lines PVDD, an end of a data signal line DL facing a fan-out line may be electrically connected to the fan-out line through a conductive structure overlapping other film layers, and the reset signal lines VREF may also be electrically connected to each other through a conductive structure overlapping other film layers, or may also be electrically connected to a pad (not shown in FIG. 10).

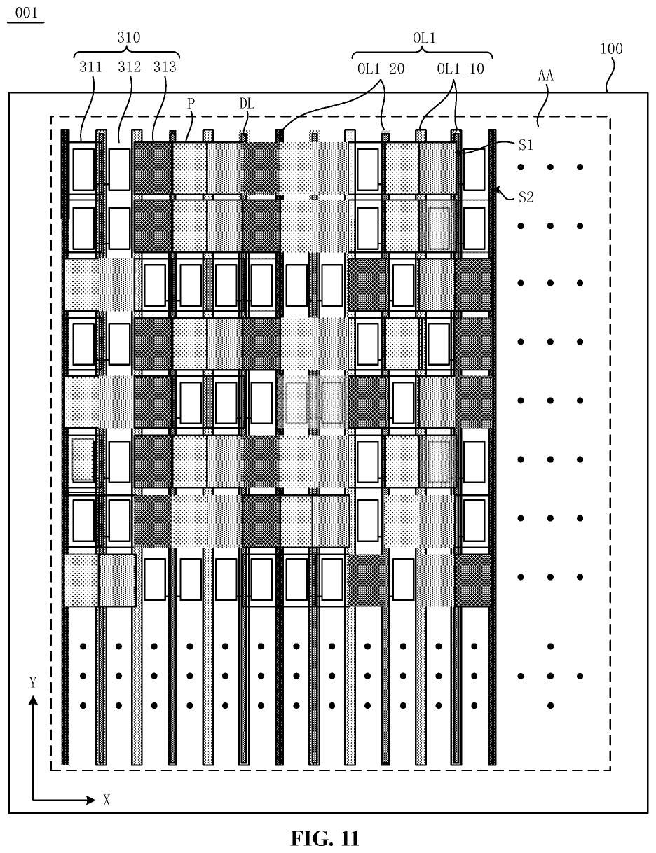

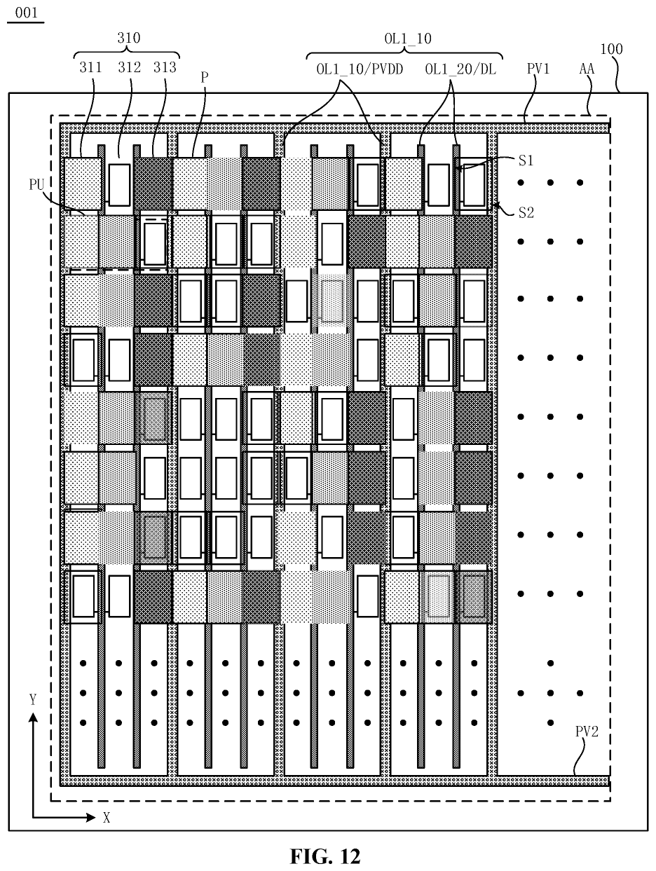

To facilitate feature extraction and better positioning during visual recognition by the visual inspection system, the embodiments of the present disclosure also provide an array substrate. In one or more embodiments, FIG. 11 is another schematic top view of an array substrate according to an embodiment of the present disclosure. Referring to FIG. 11, the first light-shielding lines OL1 include first-type light-shielding lines OL1_10 and second-type light-shielding lines OL1_20. As shown in FIG. 12, along the first direction X, lengths of the first-type light-shielding lines OL1_10 are greater than lengths of the second-type light-shielding lines OL1_20.

The first-type light-shielding lines OL1_10 may be any of the first light-shielding lines OL1, and the second-type light-shielding lines OL1_20 may be any of the first light-shielding lines OL1 excluding the first-type light-shielding lines OL1_10. The first-type light-shielding lines OL1_10 and the second-type light-shielding lines OL1_20 may be disposed in a same layer or in different layers, which is not limited in the embodiments of the present disclosure.

In an example, the color-filter structure 310 includes a red color-filter structure 311, a green color-filter structure 312 and a blue color-filter structure 313. An area of the green color-filter structure 312 is smaller than an area of the red color-filter structure 311 and the area of the green color-filter structure 312 is smaller than an area of the blue color-filter structure 313. An orthographic projection of the green color-filter structure 312 on the plane of the substrate 100 overlaps an orthographic projection of the green sub-pixel on the plane of the substrate 100. Since the luminous efficiency of the green sub-pixel is high, the area of the green sub-pixel and the area of the green color-filter structure 312 may be configured to be small. However, a smaller green color-filter structure 312 is more difficult to fabricate and more prone to misalignment. In an embodiment, the orthographic projections of the first-type light-shielding lines OL1_10 on the plane of the substrate 100 may be configured to overlap the orthographic projection of the green color-filter structure 312 on the plane of the substrate 100, and the orthographic projections of the second-type light-shielding lines OL1_20 on the plane of the substrate 100 do not overlap the orthographic projection of the green color-filter structure 312 on the plane of the substrate 100. Alternatively, the orthographic projections of the first-type light-shielding lines OL1_10 in the plane of the substrate 100 do not overlap the orthographic projection of the green color-filter structure 312 in the plane of the substrate 100, and the orthographic projections of the second-type light-shielding lines OL1_20 in the plane of the substrate 100 overlap the orthographic projection of the green color-filter structure 312 in the plane of the substrate 100. The lengths of the first-type light-shielding lines OL1_10 and the lengths of the second-type light-shielding lines OL1_20 along the first direction X are configured to be different, so that the first-type light-shielding lines OL1_10 and the second-type light-shielding lines OL1_20 can be quickly recognized based on size characteristics of the first light-shielding lines OL1. In this manner, the position of the green color-filter structure 312 can be quickly recognized based on the first-type light-shielding lines OL1_10 and the second-type light-shielding lines OL1_20. In an aspect, this facilitates quickly detecting misalignment of the green color-filter structure 312. In another aspect, whether the color of the red color-filter structure 311 and the color of the blue color-filter structure 313 adjacent to the green color-filter structure 312 are accurate can be quickly determined based on the position of the green color-filter structure 312, facilitating improving the detection efficiency and accuracy.

In one or more embodiments, FIG. 12 is another schematic top view of an array substrate according to an embodiment of the present disclosure. Referring to FIG. 12, the array substrate 001 includes multiple pixel units PU arranged in an array in the display area AA. The pixel unit PU includes multiple sub-pixels P arranged along the first direction. The orthographic projections of the first-type light-shielding lines OL1_10 on the plane of the substrate 100 are located between the orthographic projections of adjacent pixel units PU arranged along the first direction X on the plane of the substrate 100, and the orthographic projections of the second-type light-shielding lines OL1_20 on the plane of the substrate 100 overlap the orthographic projections of the pixel units PU on the plane of the substrate 100.

Specifically, the first light-shielding lines OL1 arranged in the region between adjacent pixel units PU arranged along the first direction X are the first-type light-shielding lines OL1_10, and the size of the first-type light-shielding lines OL1_10 in the first direction X is larger, facilitating the feature extraction and better positioning during visual recognition. The visual inspection system can quickly recognize the first-type light-shielding lines OL1_10 and the pixel units PU adjacent to the first-type light-shielding lines OL1_10. Therefore, whether the color of the color-filter structure 310 in the configuration area of each sub-pixel P in the pixel units PU is accurate can be quickly determined based on the pixel units PU, thus facilitating improving the detection efficiency and accuracy and avoiding the overall misalignment of the color-filter structure 310.

In another alternative embodiment, with continued reference to FIG. 12, the first-type light-shielding lines OL1_10 also serve as power signal lines PVDD. At least one of the second-type light-shielding lines OL1_20 also serves as a data signal line DL. The first-type light-shielding lines OL1_10 with a larger size along the first direction X serve as the power signal lines PVDD, facilitating reducing the impedance of the power signal lines PVDD and reducing the transmission voltage drop.

In an example, the pixel units PU include three sub-pixels P arranged along the first direction, and the first light-shielding lines OL1 arranged in the region between adjacent pixel units PU arranged along the first direction X may be the first-type light-shielding lines OL1_10. The first-type light-shielding lines OL1_10 may also serve as the power signal lines PVDD. The first light-shielding lines OL1 not arranged in the region between adjacent pixel units PU arranged along the first direction X may be the second-type light-shielding lines OL1_20, and the second-type light-shielding lines OL1_20 may also serve as the data signal lines DL. Part of the data signal lines DL may be electrically connected to the sub-pixels P in two pixel columns, and part of the data signal lines DL may be electrically connected to the sub-pixels P in one pixel column. On this basis, the reset signal lines VREF may be configured to extend along the first direction X. Alternatively, the reset signal lines VREF may be configured as transparent conductive lines and to extend along the second direction Y. Alternatively, the reset signal lines VREF may be configured to extend along the second direction Y, and orthographic projections of the reset signal lines VREF on the plane of the substrate 100 overlap orthographic projections of the first light-shielding lines OL1 on the plane of the substrate 100.

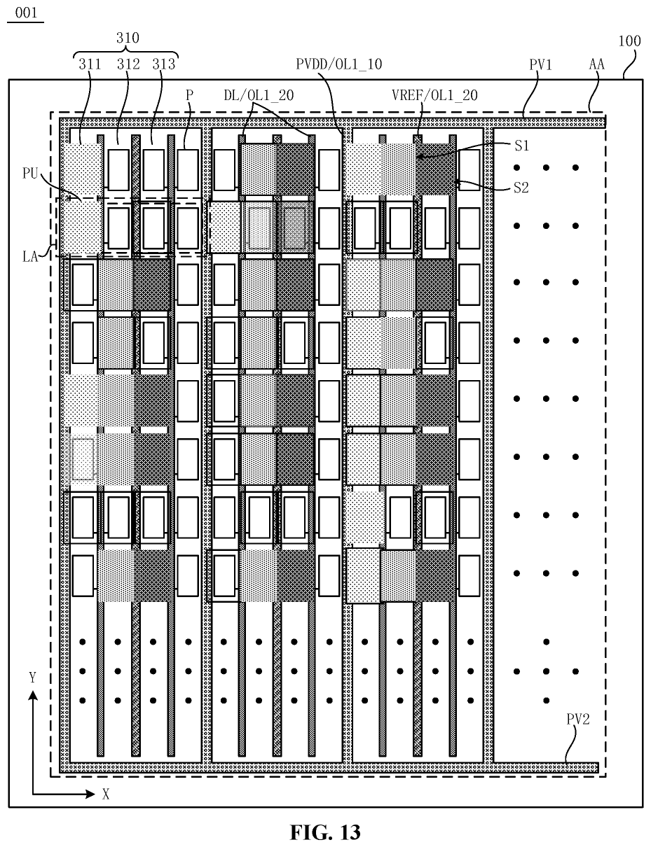

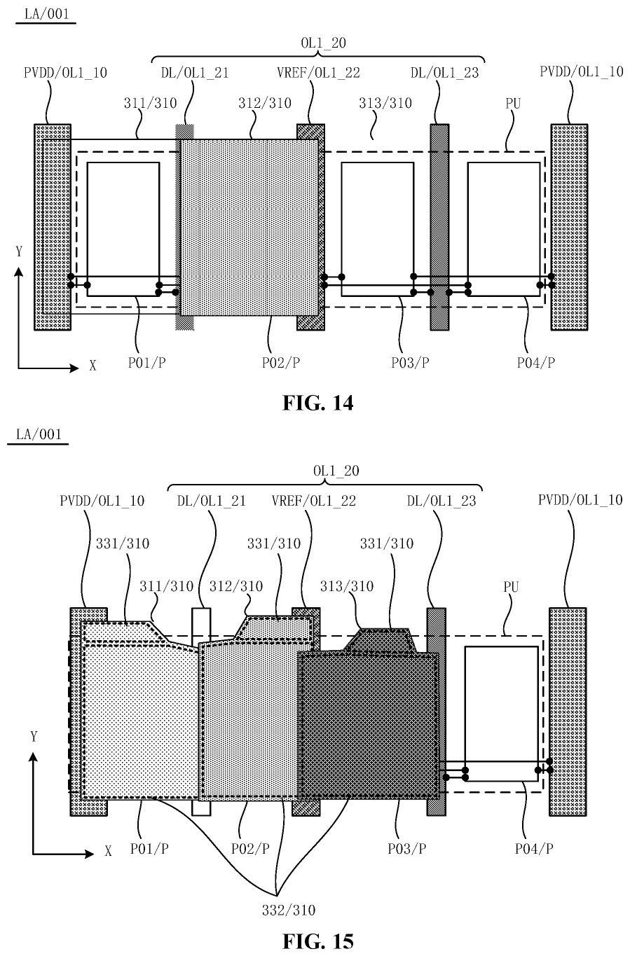

In another alternative embodiment, FIG. 13 is another schematic diagram of an array substrate according to an embodiment of the present disclosure, and FIG. 14 is an enlarged schematic diagram of a local area LA in FIG. 13. Referring to FIGS. 13 and 14, the array substrate 001 includes multiple pixel units PU arranged in an array in the display area AA. The pixel units PU include a first-color sub-pixel P01, a second-color sub-pixel P02, a third-color sub-pixel P03 and a fourth-color sub-pixel P04 arranged along the first direction.

An orthographic projection of one of the first-type light-shielding lines OL1_10 on the plane of the substrate 100 is located between the orthographic projection of the first-color sub-pixel P01 and the orthographic projection of the fourth-color sub-pixel P04 on the plane of the substrate 100. The second-type light-shielding lines OL1_20 include a first routing line OL1_21, a second routing line OL1_22 and a third routing line OL1_23. An orthographic projection of the first routing line OL1_21 on the plane of the substrate 100 is located between the orthographic projection of the first-color sub-pixel P01 and the orthographic projection of the second-color sub-pixel P02 on the plane of the substrate 100. An orthographic projection of the second routing line OL1_22 on the plane of the substrate 100 is located between the orthographic projection of the second-color sub-pixel P02 and the orthographic projection of the third-color sub-pixel P03 on the plane of the substrate 100. An orthographic projection of the third routing line OL1_23 on the plane of the substrate 100 is located between the orthographic projection of the third-color sub-pixel P03 and the orthographic projection of the fourth-color sub-pixel P04 on the plane of the substrate 100.

The first-type light-shielding lines OL1_10 also serve as the power signal lines PVDD. The first routing line OL1_21 and the third routing line OL1_23 in the second-type light-shielding lines OL1_20 also serve as data signal lines DL, and the second routing line OL1_22 also serves as a reset signal line VREF.

In an example, within the same pixel unit PU, the first-color sub-pixel P01 and the second-color sub-pixel P02 may be electrically connected to the first routing line OL1_21 that also serves as the data signal line DL, and the third-color sub-pixel P03 and the fourth-color sub-pixel P04 may be electrically connected to the third routing line OL1_23 that also serves as the data signal line DL. The first-color sub-pixel P01, the second-color sub-pixel P02, the third-color sub-pixel P03 and the fourth-color sub-pixel P04 within the same pixel unit PU may also be electrically connected to a same second routing line OL1_22 that also serves as the reset signal line VREF. Within the same pixel unit PU, the first-color sub-pixel P01 and the second-color sub-pixel P02 may be electrically connected to the first-type light-shielding lines OL1_10 that are adjacent to the first-color sub-pixel P01 and also serve as the power signal lines PVDD, and the third-color sub-pixel P03 and the fourth-color sub-pixel P04 may be electrically connected to the first-type light-shielding lines OL1_10 that are adjacent to the fourth-color sub-pixel P04 and also serve as the power signal lines PVDD. The first-type light-shielding lines OL1_10 also serve as the power signal lines PVDD, two of the second-type light-shielding lines OL1_20 (the first routing line OL1_21 and the third routing line OL1_23) serve as the data signal lines DL, and one of the second-type light-shielding lines OL1_20 (the second routing line OL1_22) serves as the reset signal line VREF, so that the reset signal line VREF does not need to be configured separately, facilitating reducing the number of film layers, simplifying the process, and lowering the fabrication cost.

On the basis of the above embodiments, the sub-pixels P in the pixel units PU adjacent to the first-type light-shielding lines OL1_10 are white sub-pixels.

In an example, referring to FIGS. 13 and 14, the first-color sub-pixel P01 is a white sub-pixel. Alternatively, the fourth-color sub-pixel P04 is a white sub-pixel. In this manner, the first-type light-shielding lines OL1_10 with a large size along the first direction X may be disposed adjacent to the white sub-pixel, and no color-filter structure 310 or a transparent color-filter structure 310 may be provided above the white sub-pixel. After the display area AA of the array substrate 001 is captured by the visual inspection system to acquire the detection image, the position of the first-type light-shielding lines OL1_10 with a large size along the first direction X in the detection image can be intuitively acquired and recognized, thus facilitating feature recognition and better positioning.

On the basis of the above embodiments, with continued reference to FIGS. 13 and 14, along the first direction X, the length of the second routing line OL1_22 is greater than the length of the first routing line OL1_21, and the length of the second routing line OL1_22 is greater than the length of the third routing line OL1_23.

In an example, the size of the second routing line OL1_22 that also serves as the reset signal line VREF in the first direction X is larger than the sizes of the first routing line OL1_21 and the third routing line OL1_23 that also serve as the data signal lines DL in the first direction X. The reset signal line VREF is typically used to transmit a fixed-potential signal. In an aspect, the size of the second routing line OL1_22 that also serves as the reset signal line VREF in the first direction X is increased, facilitating reducing the impedance of the reset signal line VREF and reducing the transmission voltage drop. In another aspect, the size of the second routing line OL1_22 that also serves as the reset signal line VREF in the first direction X is different from the sizes of the first routing line OL1_21 and the third routing line OL1_23 that also serve as the data signal lines DL in the first direction X, facilitating feature extraction, rapid positioning and accurate detection of the positions of sub-pixels P of different colors within the same pixel unit PU.

On this basis, with continued reference to FIGS. 13 and 14, the size of the second routing line OL1_22 that also serves as the reset signal line VREF in the first direction X is smaller than the sizes of the first-type light-shielding lines OL1_10 that also serve as the power signal lines PVDD in the first direction X. In an example, after the pixel units PU are quickly detected through the first-type light-shielding lines OL1_10 with a larger size in the first direction X, the sub-pixels P with different colors within the pixel units PU can be further accurately detected through the first routing line OL1_21, the second routing line OL1_22 and the third routing line OL1_23 with different size characteristics in the first direction X, facilitating improving the detection efficiency and accuracy.

It should be noted that, for ease of explanation, FIGS. 13 and 14 only show that the top view shapes of the color-filter structures 310 are both rectangular structures, and the sizes of the color-filter structures 310 with different colors are basically the same, but it is not limited thereto. In one or more embodiments, the color-filter structures 310 may also be irregular, and/or the sizes of the color-filter structures 310 with different colors may be different.

In one or more embodiments, FIG. 15 is another enlarged schematic diagram of a local area LA in FIG. 13. Referring to FIG. 15, the color-filter structure 310 includes a first color-filter portion 331 and a second color-filter portion 332 arranged along the second direction Y. Along the first direction X, a length of the first color-filter portion 331 and a length of the second color-filter portion 332 are different.

In an example, the size of an end of the color-filter structure 310 in the first direction X may be adjusted according to the process error during the fabrication of the color-filter structure 310, so that the size of the first color-filter portion 331 and the size of the second color-filter portion 332 in the first direction X are different. The end refers to an end of the color-filter structure 310 in the second direction Y, which may be an end of the color-filter structure 310 on any side in the second direction Y or may be ends of the color-filter structure 310 on both sides in the second direction Y. In other words, the first color-filter portion 331 and/or the second color-filter portion 332 may be the end of the color-filter structure 310 in the second direction Y. The size of the first color-filter portion 331 and/or the size of the second color-filter portion 332 in the first direction X may change. As a result, light leakage only exists in a small part of the color-filter structure 310 and/or only a small part of the color-filter structure 310 covers above other sub-pixels P when the position of the color-filter structure 310 deviates slightly due to process errors, so that the area of light leakage and/or incorrect color emission is smaller and a transition area is formed. In other words, the light leakage and/or the incorrect color display is discontinuous and intermittent in the area in the second direction Y, avoiding the light leakage or the incorrect color display being continuous in the area in the second direction Y, thereby effectively compensating for visually visible periodic stripe unevenness caused by process errors during the fabrication process. On this basis, the length of the first color-filter portion 331 and/or the length of the second color-filter portion 332 in the first direction X may be smaller than the maximum length of the color-filter structure in the first direction X.

In one or more embodiments, the color-filter structure 310 includes a red color-filter structure 311, a green color-filter structure 312 and a blue color-filter structure 313. An area of the blue color-filter structure 313 is larger than an area of the red color-filter structure 311, and an area of the red color-filter structure 311 is larger than an area of the green color-filter structure 312, and/or, along the first direction X, a length of the blue color-filter structure 313 is greater than a length of the red color-filter structure 311, and a length of the red color-filter structure 311 is greater than a length of the green color-filter structure 312. In this manner, differences in luminous efficiency of sub-pixels P with different colors and differences in human eye perception of different colors can be compensated.

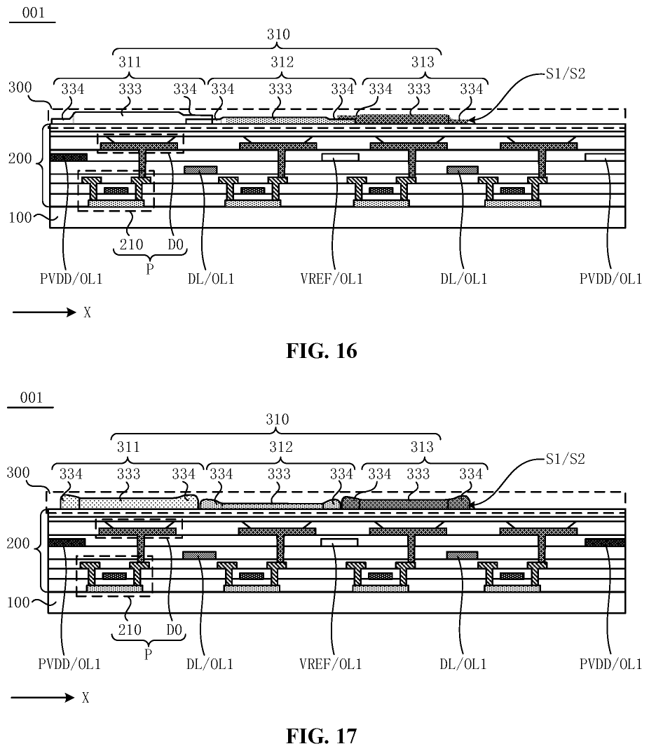

In one or more other embodiments, FIG. 16 is another schematic diagram of a film layer structure of an array substrate according to an embodiment of the present disclosure. Referring to FIG. 16, the color-filter structures 310 of at least two colors have different thicknesses along the direction perpendicular to the plane of the substrate 100.

In an example, with continued reference to FIG. 16, the color-filter structure 310 includes a red color-filter structure 311, a green color-filter structure 312 and a blue color-filter structure 313. Since the green color-filter material has a strong absorption capacity for red light and blue light, a thickness of the green color-filter structure 312 may be configured to be relatively thin. Since the red color-filter material has a weak absorption capacity for green light and blue light, a thickness of the red color-filter structure 311 may be configured to be relatively thick, and the absorption path of the red color-filter structure 311 for blue light and green light can be extended, enabling the red color-filter structure 311 to absorb blue light and green light to a greater extent and ensuring high purity of red light. Along the direction perpendicular to the plane of the substrate 100, the thickness of the red color-filter structure 311 is greater than the thickness of the blue color-filter structure 313, and the thickness of the blue color-filter structure 313 is greater than the thickness of the green color-filter structure 312, thereby effectively compensating for the display error caused by different color filtering capabilities of the color-filter structures 310 of different colors and facilitating improving the display effect.

In one or more embodiments, different sub-pixels of different colors have different luminous efficiencies, and the sensitivity of the human eyes to different colors is also different. The thickness relationship of color-filter structures 310 of different colors may be adjusted according to the luminous efficiency difference and/or human eye perception difference. The thickness relationship of color-filter structures 310 of different colors is not limited to the thickness of the red color-filter structure 311 being greater than the thickness of the blue color-filter structure 313, and the thickness of the blue color-filter structure 313 being greater than the thickness of the green color-filter structure 312.

In another embodiment, the color-filter structure 310 includes a third color-filter portion 333 and a fourth color-filter portion 334. An orthographic projection of the fourth color-filter portion 334 on the plane of the substrate 100 at least partially surrounds an orthographic projection of the third color-filter portion 333 on the plane of the substrate 100. Along the direction perpendicular to the plane of the substrate 100, a thickness of the third color-filter portion 333 is not equal to a thickness of the fourth color-filter portion 334.

In an example, with continued reference to FIG. 16, along the first direction X, the fourth color-filter portions 334 are located on the opposite sides of the third color-filter portion 333. Along the direction perpendicular to the plane of the substrate 100, the thickness of the fourth color-filter portion 334 is smaller than the thickness of the third color-filter portion 333, enabling the thickness of the middle region of the color-filter structure 310 to be larger, thus facilitating enhancing the color filtering capability of the middle region of the color-filter structure 310 and ensuring the purity of the emitted light in the middle region. Moreover, the edge regions of the color-filter structure 310, especially the edge regions located on the opposite sides of the middle region along the first direction X, are relatively thin. In this manner, when orthographic projections of adjacent fourth color-filter portions 334 of the color-filter structure 310 arranged along the first direction X on the plane of the substrate 100 overlap each other, the thickness of the overlapping region can be reduced, and a situation where a large difference between the thickness of the overlapping region and the thickness of the middle region of the color-filter structure 310 caused by severe stacking of the overlapping parts affects subsequent processing can be avoided.

In other embodiments, the case where, along the first direction X, the fourth color-filter portion 334 is located on opposite sides of the third color-filter portion 333 is continuously taken as an example. FIG. 17 is another schematic diagram of a film layer structure of an array substrate according to an embodiment of the present disclosure. Referring to FIG. 17, along the direction perpendicular to the plane of the substrate 100, the thickness of the fourth color-filter portion 334 may also be greater than the thickness of the third color-filter portion 333. The absorption path of light can be increased through the fourth color-filter portion 334 to better absorb light of other colors, and the color filtering capability in the edge region of the color-filter structure 310 can be enhanced. In this manner, light from adjacent sub-pixels P can be better filtered, and the light crosstalk between adjacent sub-pixels P can be reduced. For adjacent sub-pixels P that need to exhibit white during display, the color-filter structure 310 may not be arranged above the sub-pixels P, and the fourth color-filter portion 334 can block outgoing light of the adjacent sub-pixel P without the color-filter structure 310 from emitting to an upper part of a sub-pixel P with the color-filter structure 310. The greater the thickness of the fourth color-filter portion 334, the stronger the blocking capability, which is also beneficial to reducing the light crosstalk of adjacent sub-pixels P, especially adjacent sub-pixels P that appear white during display.

On this basis, when the thickness of the fourth color-filter portion 334 is large, orthographic projections of the fourth color-filter portions 334 of color-filter structures 310 arranged adjacent to each other along the first direction X on the plane of the substrate 100 may not overlap, and there may be a gap between the fourth color-filter portions 334 of the color-filter structures 310 arranged adjacent to each other along the first direction X. However, due to the large thickness of the fourth color-filter portions 334, at the same time, light emitted from the sub-pixel P to the gap usually exits obliquely. That is, light rays are not perpendicular to the plane of the substrate 100, so that the light rays emitted to the gap can be blocked by the fourth color-filter portion 334, light rays of other colors can be filtered out, light crosstalk between adjacent sub-pixels P can also be reduced, and the display contrast can be increased.

It can be understood that FIGS. 16 and 17 only show that the fourth color-filter portion 334 is located on opposite sides of the third color-filter portion 333 along the first direction X, but it is not limited to this. The fourth color-filter portion 334 can also be located on one side of the third color-filter portion 333 along the first direction X, or the fourth color-filter portion 334 can also be located on one side or both sides of the third color-filter portion 333 along the second direction Y.

On the basis of the above embodiment, an orthographic projection of the fourth color-filter portion 334 on the plane of the substrate 100 overlaps an orthographic projection of a first light-shielding line OL1 on the plane of the substrate 100. On the one hand, this ensures that an orthographic projection of the first edge S1 and an orthographic projection of the second edge S2 of the color-filter structure 310 on the plane of the substrate 100 can overlap the orthographic projection of the first light-shielding line OL1 on the plane of the substrate 100. On the other hand, since the first light-shielding line OL1 is located between adjacent pixel columns and an orthographic projection of the first light-shielding line OL1 on the plane of the substrate 100 does not overlap an orthographic projection of a sub-pixel P on the plane of the substrate 100, an orthographic projection of the fourth color-filter portion 334 on the plane of the substrate 100 does not overlap an orthographic projection of the sub-pixel P on the plane of the substrate 100. In this manner, the sub-pixel P can present a corresponding color through the third color-filter portion 333 of the color-filter structure 310 regardless of the thickness of the fourth color-filter portion 334, thereby avoiding the fourth color-filter portion 334 affecting light emission of the sub-pixel P.

From the above, it can be seen that the first light-shielding line OL1 can be provided in the same layer as the bottom light-shielding structure, or can also serve as signal lines such as a data signal line DL, a power signal line PVDD, and a reset signal line VREF, and the first light-shielding line OL1 can be a metal light-shielding line. On this basis, orthographic projections of adjacent color-filter structures 310 arranged along the first direction X on the plane of the substrate 100 can be configured to overlap each other, and an overlapping region of the orthographic projections of the adjacent color-filter structures 310 arranged along the first direction X on the plane of the substrate 100 overlaps an orthographic projection of the first light-shielding line OL1 on the plane of the substrate 100.

For example, referring to FIGS. 14, 15 and 16, orthographic projections of adjacent color-filter structures 310 arranged along the first direction X overlap on the plane of the substrate 100, and overlapping regions can form black opaque regions, which is beneficial to reducing the light crosstalk of different colors between adjacent sub-pixels P, especially when the light-emitting elements D0 in the sub-pixels P in the array substrate 001 emit white light and present different colors through the color-filter structures 310. This can effectively prevent adjacent sub-pixels P from leaking white light and improve the display. For a sub-pixel P that needs to appear white during display, white light leakage between the sub-pixel P and its adjacent sub-pixels P has little influence on the actual effect. Therefore, the sub-pixel P that needs to appear white during display does not need to be provided with a color-filter structure 310, nor does it need to overlap the color-filter structure 310 above its adjacent sub-pixel P. Alternatively, when a planarization layer is formed on the side of the color-filter layer 300 facing away from the substrate 100, part of the planarization layer can fill the area above the fourth-color sub-pixel P04 as a white color-filter structure, and the white color-filter structure overlaps the color-filter structure 310 above its adjacent sub-pixel P.

In addition, the overlapping region overlaps an orthographic projection of the first light-shielding line OL1 on the plane of the substrate 100. On the one hand, this can reduce interference of the overlapping region on alignment abnormality detection of the color-filter structure 310 and improve detection efficiency and accuracy. On the other hand, this can also reduce reflected light from the metal light-shielding line, which is beneficial to improving the display effect of the array substrate.

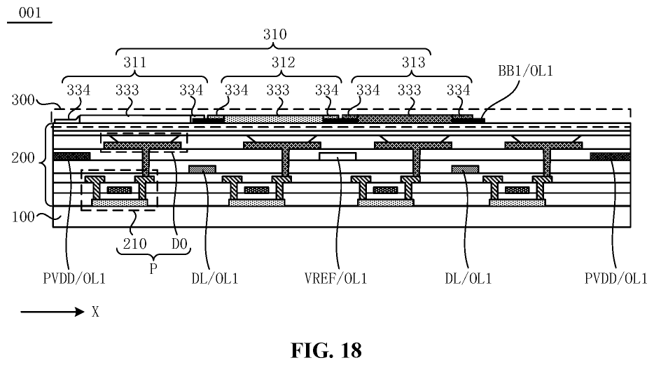

In one or more embodiments, FIG. 18 is a schematic diagram of a film layer structure of an array substrate according to an embodiment of the present disclosure. Referring to FIG. 18, the light-emitting functional layer 200 includes multiple light-emitting elements D0 and a pixel driving circuit 210. The array substrate 001 further includes a black light-shielding layer. The black light-shielding layer includes multiple first light-shielding portions BB1 arranged along the first direction X and extending along the second direction Y. An orthographic projection of a first light-shielding portion BB1 on the plane of the substrate 100 does not overlap an orthographic projection of a light-emitting element D0 on the plane of the substrate 100. An orthographic projection of the first light-shielding portion BB1 on the plane of the substrate 100 overlaps an orthographic projection of a first light-shielding line OL1 on the plane of the substrate 100.

For example, the black light-shielding layer may be a black matrix layer. In the black matrix layer, orthographic projections of first light-shielding portions BB1 arranged along the first direction X and extending along the second direction Y on the plane of the substrate 100 need to overlap orthographic projections of first light-shielding lines OL1 on the plane of the substrate 100. If the black matrix layer is arranged on a side of the color-filter layer 300 facing the substrate 100, the overlapping relationship on the plane of the substrate 100 can avoid the black matrix layer interfering with alignment abnormality detection of the color-filter structure 310. In addition, if the black matrix layer is arranged on the side of the color-filter layer 300 facing the substrate 100, the first light-shielding portions BB1 can be correspondingly arranged at an overlapping region or a gap of adjacent color-filter structures 310 arranged along the first direction X, thereby avoiding dislocation between a light-emitting region defined by the black matrix layer and a configuration region of the color-filter structure 310 and avoiding affecting the display effect. Meanwhile, whether the black matrix layer is arranged on the side of the color-filter layer 300 facing the substrate 100 or on a side of the color-filter layer 300 facing away from the substrate 100, the black matrix layer can reduce light crosstalk of different colors between adjacent sub-pixels P and reduce process requirements for fabricating the color-filter structure 310. That is, orthographic projections of adjacent color-filter structures 310 arranged along the first direction X on the plane of the substrate 100 are allowed not to overlap, or a small positional deviation along the first direction X is allowed, which is beneficial to improving production efficiency and reducing fabrication cost.

In an embodiment, the black light-shielding layer is located between the light-emitting functional layer 200 and the color-filter layer 300, and the first light-shielding line OL1 can be reused as the first light-shielding portion BB1.

For example, after the light-emitting functional layer 200 is fabricated, a black light-shielding layer can be formed on a side of the light-emitting functional layer 200 facing away from the substrate 100, and then a color-filter structure 310 can be fabricated on a side of the black light-shielding layer facing away from the substrate 100. An orthographic projection of the fourth color-filter portion 334 of the color-filter structure 310 on the plane of the substrate 100 may overlap an orthographic projection of the black light-shielding layer on the plane of the substrate 100. If they overlap, along a direction perpendicular to the plane of the substrate 100, a thickness of the fourth color-filter portion 334 may be configured to be smaller than a thickness of the third color-filter portion 333, as shown in FIG. 18. If they do not overlap, along the direction perpendicular to the plane of the substrate 100, the thickness of the fourth color-filter portion 334 may be configured to be greater than the thickness of the third color-filter portion 333 (not shown in FIG. 18).

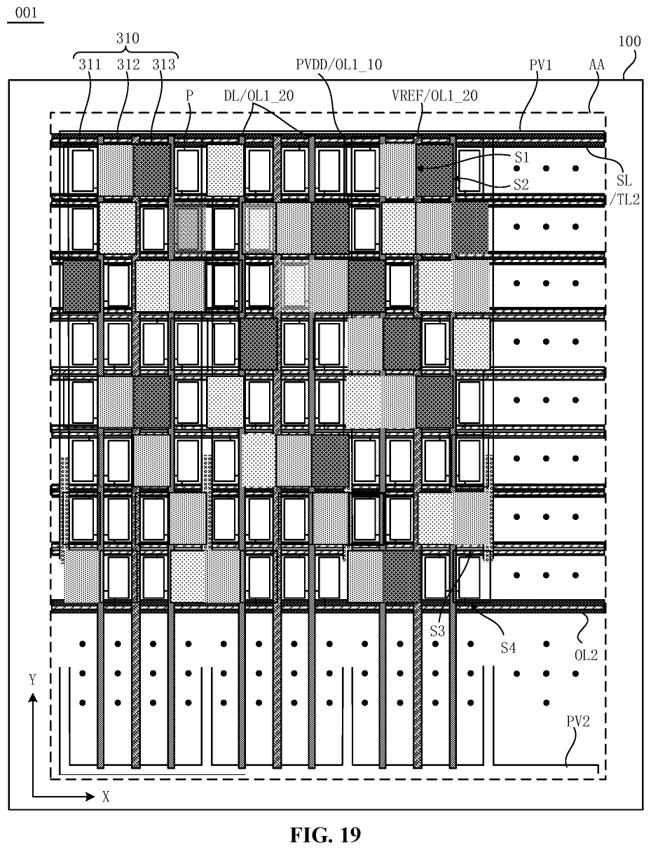

In one or more embodiments, FIG. 19 is a schematic top view of an array substrate according to an embodiment of the present disclosure. Referring to FIG. 19, along the second direction Y, adjacent color-filter structures 310 have different colors. The array substrate 001 further includes multiple second light-shielding lines OL2 located on a side of the color-filter layer 300 facing the substrate 100, arranged along the second direction Y and extending along the first direction X. The color-filter structure 310 includes a third edge S3 and a fourth edge S4 arranged opposite to each other along the second direction Y. Orthographic projections of the third edge S3 and the fourth edge S4 on the plane of the substrate 100 overlap orthographic projections of the second light-shielding lines OL2 on the plane of the substrate 100.

The second light-shielding lines OL2 also include an opaque material, so that the light transmittance of the second light-shielding lines OL2 is low. The second light-shielding lines OL2 may include the same material as the first light-shielding lines OL1 and may be located in the same film layer position as the first light-shielding lines OL1, but it is not limited to this. In other embodiments, the second light-shielding lines OL2 and the first light-shielding lines OL1 may include different materials and/or may be located in different film layer positions. Alternatively, part of the second light-shielding lines OL2 may be located in the same layer as part of the first light-shielding lines OL1, and part of the second light-shielding lines OL2 and part of the first light-shielding lines OL1 may be located in different film layer positions.

Illustratively, the third edge S3 and the fourth edge S4 of the color-filter structure 310 are arranged along the second direction Y and extend along the first direction X. In an embodiment, orthographic projections of the third edge S3 and the fourth edge S4 on the plane of the substrate 100 are both located within a contour (including a contour edge) of an orthographic projection of a second light-shielding line OL2 on the plane of the substrate 100. Orthographic projections of the third edge S3 and the fourth edge S4 of the same color-filter structure 310 on the plane of the substrate 100 are located within contours (including contour edges) of orthographic projections of different second light-shielding lines OL2 on the plane of the substrate 100, respectively. In another embodiment, orthographic projections of the second light-shielding lines OL2 on the plane of the substrate 100 can be used to divide configuration areas of pixel rows. That is, along the second direction Y, second light-shielding lines OL2 can be arranged on opposite sides of each pixel row, so that orthographic projections of the third edge S3 and the fourth edge S4 of the color-filter structure 310 on the plane of the substrate 100 can be located within contours (including contour edges) of orthographic projections of the second light-shielding lines OL2 on the plane of the substrate 100. In an embodiment, when the array substrate 001 is provided with a first auxiliary power supply line PV1 and a second auxiliary power supply line PV2 arranged along the second direction Y and extending along the first direction X, the first auxiliary power supply line PV1 and the second auxiliary power supply line PV2 can also serve as the second light-shielding lines OL2 (not shown in FIG. 19).

When alignment abnormality detection of the color-filter structure 310 is performed, along the second direction Y, if the color-filter structure 310 exists in part of a region between two adjacent second light-shielding lines OL2 and does not exist in another part of the region, that is, if the region between the two adjacent second light-shielding lines OL2 exhibits both a color of the color-filter structure 310 and a color of a light source (usually white light), this may be caused by an abnormally small size of part of the color-filter structure 310 along the second direction Y, such that the color-filter structure 310 does not completely cover a sub-pixel configuration area between the two adjacent second light-shielding lines OL2. Alternatively, this may be caused by an abnormally large size of part of the color-filter structure 310 along the second direction Y, such that the color-filter structure 310 extends into other sub-pixel configuration areas arranged along the second direction Y and the third edge S3 and/or the fourth edge S4 is not located within a contour of the second light-shielding lines OL2. In this case, it should be determined that an alignment abnormality of the color-filter structure 310 exists.

If a contour of a second light-shielding line OL2 is different from a contour of the second light-shielding line OL2 immediately after fabrication, for example, when the contour of the second light-shielding line OL2 is straight immediately after fabrication and changes after the color-filter structure 310 is formed, an abnormal protrusion along the second direction Y may exist in a local area of the second light-shielding line OL2. The abnormal protrusion is an opaque black area, which may be caused by an abnormally large size of part of the color-filter structure 310 along the second direction Y. An orthographic projection of the color-filter structure 310 on the plane of the substrate 100 overlaps orthographic projections of multiple sub-pixels P arranged along the second direction Y on the plane of the substrate 100 and overlaps color-filter structures 310 in other sub-pixel configuration areas to form a black opaque region. In this case, the third edge S3 and/or the fourth edge S4 is not located within the contour of the second light-shielding lines OL2, and it should also be determined that an alignment abnormality of the color-filter structure 310 exists.

According to an embodiment of the present disclosure, by arranging multiple second light-shielding lines OL2 arranged along the second direction Y and extending along the first direction X on a side of the color-filter layer 300 facing the substrate 100, whether alignment abnormality of the color-filter structure 310 exists along the second direction Y can be detected by using the second light-shielding lines OL2 as references, thereby improving the display effect. Moreover, by configuring orthographic projections of the third edge S3 and the fourth edge S4 of the color-filter structure 310 on the plane of the substrate 100 to overlap orthographic projections of the second light-shielding lines OL2 on the plane of the substrate 100, an alignment abnormality of the color-filter structure 310 can be determined when an orthographic projection of the third edge S3 or an orthographic projection of the fourth edge S4 on the plane of the substrate 100 does not overlap orthographic projections of the second light-shielding lines OL2 on the plane of the substrate 100, which is beneficial to simplifying the color-filter structure detection method and improving detection efficiency and accuracy.

On the basis of the above embodiment, with reference to FIG. 19, the light-emitting functional layer 200 further includes multiple second signal lines TL2 extending along the first direction X. Along the second direction Y, a length of the second light-shielding line OL2 is greater than a length of the second signal line TL2. Specifically, along the second direction Y, the second light-shielding line OL2 has a larger size, which is beneficial to feature extraction and enables quick identification of the second light-shielding line OL2 used to detect whether alignment abnormality of the color-filter structure 310 exists along the second direction Y.

The second signal lines TL2 include, but are not limited to, signal routing lines extending along the first direction X, such as power signal lines, reset signal lines, scanning signal lines, and the like. In an embodiment, the second signal lines TL2 may also include overlapping routing lines extending along the first direction X, and these overlapping routing lines may be electrically connected to signal routing lines extending along the second direction Y.

In one or more embodiments, with continued reference to FIG. 19, the light-emitting functional layer 200 further includes multiple scanning signal lines SL arranged along the second direction Y and extending along the first direction X. More than one sub-pixel P arranged along the first direction X form a pixel row, and sub-pixels P in the same pixel row can be electrically connected to two scanning signal lines SL. In the same pixel row, two sub-pixels P connected to the same data signal line DL are respectively connected to different scanning signal lines SL. In the display area AA, an orthographic projection of a second light-shielding line OL2 on the plane of the substrate 100 covers an orthographic projection of a scanning signal line SL on the plane of the substrate 100.

It should be noted that an orthographic projection of a second light-shielding line OL2 on the plane of the substrate 100 covering an orthographic projection of a scanning signal line SL on the plane of the substrate 100 means that an orthographic projection of a scanning signal line SL in the display area AA on the plane of the substrate 100 is located within an orthographic projection contour (including contour edges) of the second light-shielding line OL2 on the plane of the substrate 100, and it is not limited to the second light-shielding line OL2 being located on a side of the scanning signal line SL facing the substrate 100 or facing away from the substrate 100.

In an example, sub-pixels P of the same pixel row are electrically connected to two scanning signal lines SL located on opposite sides of the pixel row along the second direction Y, and two scanning signal lines SL are arranged between at least some adjacent pixel rows. In the display area AA, an orthographic projection contour (including contour edges) of the second light-shielding line OL2 located between the adjacent pixel rows may include orthographic projections of the two scanning signal lines SL on the plane of the substrate 100, so that the scanning signal lines SL can be effectively prevented from interfering with alignment abnormality detection of the color-filter structure 310.

It can be understood that in other embodiments, sub-pixels P of the same pixel row can be electrically connected to two scanning signal lines SL located on the same side of the pixel row along the second direction Y. The embodiments of the present disclosure do not limit positions of the scanning signal lines SL and the pixel rows electrically connected to the scanning signal lines SL.

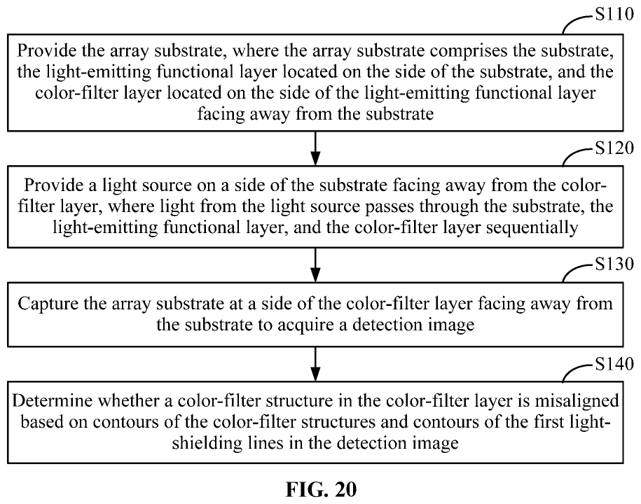

The embodiments of the present disclosure also provide a color-filter structure detection method for the array substrate provided by any embodiment of the present disclosure. FIG. 20 is a flow chart of a color-filter structure detection method of an array substrate according to an embodiment of the present disclosure. Referring to FIG. 20, the color-filter structure detection method includes the following:

S110, the array substrate is provided, where the array substrate includes a substrate, a light-emitting functional layer at one side of the substrate, and a color-filter layer at one side of the light-emitting functional layer facing away from the substrate.

The array substrate includes multiple first light-shielding lines arranged along a first direction and extending along a second direction, and the color-filter layer includes color-filter structures of at least one color.

S120, a light source is provided on a side of the substrate facing away from the color-filter layer, so that light from the light source passes through the substrate, the light-emitting functional layer, and the color-filter layer sequentially.

In one embodiment, the light source is typically a white light source and is configured to uniformly irradiate the array substrate from the substrate side. In an embodiment, a length of the light source along the first direction is greater than a length of the array substrate along the first direction, and/or a length of the light source along the second direction is greater than a length of the array substrate along the second direction, which is beneficial to uniformly irradiating the substrate side of the array substrate, so that light from the light source can sequentially pass through the substrate, the light-emitting functional layer, and the color-filter layer.

S130, the array substrate is captured at a side of the color-filter layer facing away from the substrate to acquire a detection image.

Specifically, light from the light source illuminates the color-filter layer from the side of the substrate facing away from the color-filter layer, and the array substrate is captured from the side of the color-filter layer facing away from the substrate. Since the first light-shielding lines are opaque and the color-filter structures transmit light of corresponding colors and absorb light of other colors, in the detection image, regions where the first light-shielding lines are located appear as black regions, and regions where the color-filter structures are located appear as corresponding colors.

S140, based on contours of the color-filter structures in the detection image and contours of the first light-shielding lines, whether a color-filter structure in the color-filter layer is misaligned is determined.

For example, based on contours of the color-filter structures and contours of the first light-shielding lines in the detection image, in response to a first edge and/or a second edge of a color-filter structure being identifiable in the detection image, it indicates that an orthographic projection of the first edge and/or the second edge on the plane of the substrate does not overlap an orthographic projection of a first light-shielding line on the plane of the substrate, and it is determined that the color-filter structure is misaligned. Alternatively, in response to a contour of a first light-shielding line in the detection image being different from a contour immediately after fabrication and exhibiting an abnormal protrusion along the first direction in a local region, the abnormal protrusion appearing as a black opaque region, it is determined that the color-filter structure is misaligned.

According to the color-filter structure detection method provided by the embodiments of the present disclosure, projective detection is adopted, and the first light-shielding lines in the array substrate are used as references. Whether a color-filter structure in the color-filter layer is misaligned is determined based on contours of the color-filter structures and contours of the first light-shielding lines. The detection process does not require precise focusing or distance calculation, and detection can be performed under defocused imaging conditions, thereby improving detection efficiency and detection accuracy.

On the basis of the above embodiment, orthographic projections of the first light-shielding lines on a plane of the array substrate define multiple sub-pixel regions arranged along the first direction on the plane of the array substrate, and sub-pixels are disposed in the sub-pixel regions. Each sub-pixel region corresponds to a display primary color, and each color-filter structure overlaps one of the sub-pixel regions. Determining whether the color-filter structure in the color-filter layer is misaligned based on the contours of the color-filter structures and the contours of the first light-shielding lines in the detection image includes at least one of the following: in the detection image, in response to a color of a color-filter structure overlapping a sub-pixel region not being the same as the display primary color corresponding to the sub-pixel region, determining that the color-filter structure overlapping the sub-pixel region is misaligned; or, in the detection image, in response to an orthographic projection of a first light-shielding line corresponding to a sub-pixel region on the plane of the array substrate protruding abnormally toward an adjacent sub-pixel region of the sub-pixel region, determining that the color-filter structure overlapping the sub-pixel region is misaligned.

For example, if a sub-pixel region corresponds to a red display primary color but appears green in the detection image, it indicates that a green color-filter structure is formed at this position, and the color-filter structure is misaligned. Alternatively, after a red color-filter structure is fabricated, if the sub-pixel region at this position appears white, it indicates that the red color-filter structure is misaligned. Alternatively, after the red color-filter structure is fabricated, if the sub-pixel region at this position appears partially red and partially white, it indicates that a size of the red color-filter structure at this position is abnormally small or a position is offset, and the red color-filter structure is misaligned.

A length of a first light-shielding line along the second direction is greater than a length of a color-filter structure along the second direction, and a portion of the first light-shielding line does not overlap the color-filter structure. If a local region of the first light-shielding line exhibits a length along the first direction greater than a length of a region of the first light-shielding line that does not overlap the color-filter structure, it indicates that an abnormal protrusion exists along the first direction, indicating that a size of part of the color-filter structure is abnormally large or a significant positional deviation exists along the first direction, and misalignment exists at this position.

Accordingly, without distance calculation and under defocused imaging conditions, misalignment determination can be performed by determining whether contours of the first light-shielding lines in the detection image exhibit abnormal protrusions and whether a sub-pixel region presents a color not corresponding to the display primary color of the sub-pixel region, thereby improving detection efficiency and detection accuracy.

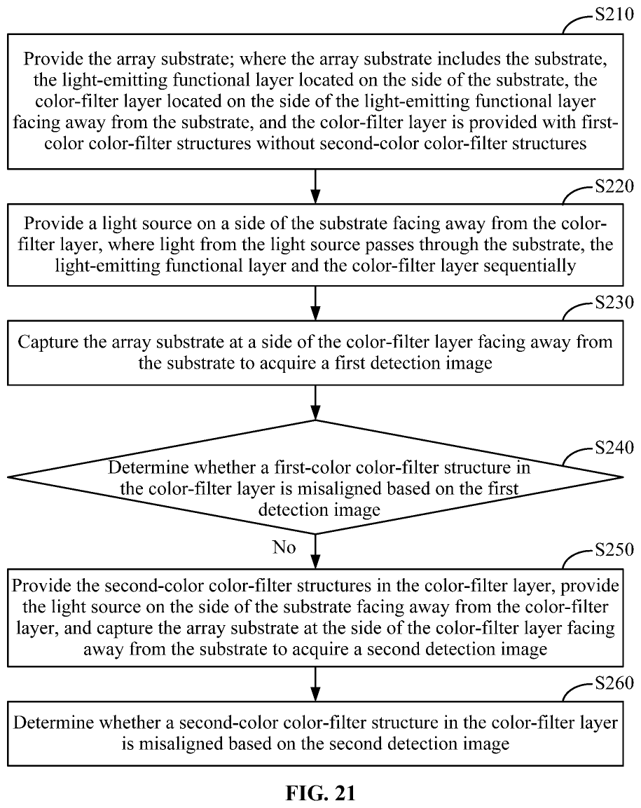

In one or more embodiments, FIG. 21 is another flow chart of a detection method for a color-filter structure of an array substrate according to an embodiment of the present disclosure. Referring to FIG. 21, the color-filter structure detection method includes the following steps:

S210, the array substrate is provided, where the array substrate includes a substrate, a light-emitting functional layer located on one side of the substrate, and a color-filter layer located on one side of the light-emitting functional layer facing away from the substrate, and the color-filter layer is provided with first-color color-filter structures without second-color color-filter structures.

For example, the array substrate includes a first sub-pixel region and a second sub-pixel region arranged along a first direction. Sub-pixels disposed in the first sub-pixel region correspond to a first display primary color, and sub-pixels disposed in the second sub-pixel region correspond to a second display primary color. A color of the first-color color-filter structures corresponds to the first display primary color, and a color of the second-color color-filter structures corresponds to the second display primary color. At this stage, the first-color color-filter structures have been formed on the surface of the first sub-pixel region, and the second-color color-filter structures have not been formed on the surface of the second sub-pixel region.

S220, A light source is provided on the side of the substrate facing away from the color-filter layer, so that light from the light source passes through the substrate, the light-emitting functional layer, and the color-filter layer sequentially.

S230, the array substrate is captured at the side of the color-filter layer facing away from the substrate to acquire a first detection image.

For example, the array substrate includes a first sub-pixel region, a second sub-pixel region, a third sub-pixel region, and other sub-pixel regions corresponding to multiple display primary colors and arranged along the first direction. In the first detection image, a color corresponding to the first-color color-filter structures is presented, and a color corresponding to the second-color color-filter structures is not presented.

S240, based on the first detection image, it is determined whether a first-color color-filter structure of the first-color color-filter structures in the color-filter layer is misaligned. In response to determining that none of the first-color color-filter structures is misaligned, step S250 is performed; and in response to determining that at least one of the first-color color-filter structures is misaligned, the first-color color-filter structures are reworked and re-fabricated.

For example, whether a first-color color-filter structure is misaligned is determined based on whether the first sub-pixel region presents a color corresponding to the first-color color-filter structures in the first detection image. If a white region appears in the first sub-pixel region or a color corresponding to the first display primary color appears in another sub-pixel region, it is determined that the first-color color-filter structures are misaligned. When misalignment exists, the first-color color-filter structures can be removed and re-fabricated, and steps S210, S220, S230, and S240 are repeated until the first detection image indicates that none of the first-color color-filter structures is misaligned.

S250, in response to none of the first-color color-filter structures being misaligned, the second-color color-filter structures are provided in the color-filter layer, providing the light source on the side of the substrate facing away from the color-filter layer, and capturing the array substrate at the side of the color-filter layer facing away from the substrate to acquire a second detection image.

For example, when the step S250 is performed, the first-color color-filter structures have been formed on the first sub-pixel region and no misalignment has been detected, and the second-color color-filter structures have been formed on the second sub-pixel region. In the second detection image, colors corresponding to the first-color color-filter structures and the second-color color-filter structures are both presented.

S260, based on the second detection image, it is determined whether a second-color color-filter structure of the second-color color-filter structures in the color-filter layer is misaligned.

For example, whether a second-color color-filter structure is misaligned can be determined based on whether the second sub-pixel region presents a color corresponding to the second-color color-filter structures in the second detection image. If a white region appears in the first sub-pixel region or a color corresponding to the second display primary color appears in another sub-pixel region, it is determined that the second-color color-filter structures are misaligned. Alternatively, whether the second-color color-filter structures are misaligned can also be determined based on whether an abnormal protrusion of a contour of a first light-shielding line exists in the first sub-pixel region; in response to an abnormal protrusion existing, it is also determined that the second-color color-filter structures are misaligned. When the second-color color-filter structures are misaligned, the second-color color-filter structures in the array substrate can be removed and re-fabricated, and steps S250 and S260 are sequentially performed until the second detection image indicates that the second-color color-filter structures are no longer misaligned. In response to determining that the second-color color-filter structures are not misaligned, fabrication of remaining color-filter structures may continue, and corresponding detection may be performed in a similar manner, until color-filter structures of all colors have been formed.

According to the embodiments of the present disclosure, alignment abnormality detection is performed once after each color-filter structure of one color is fabricated, so that rework can be performed in time after misalignment occurs. This is beneficial to improving product yield and reducing workload, and avoids performing detection only after all color-filter structures are fabricated, in which case rework workload would be relatively large when misalignment exists.

It can be understood that the above detection of color-filter structures may be performed as global detection for all positions in the display area, or may be performed for a local region in the display area, or multiple regions may be set in the display area for sampling inspection. The embodiments of the present disclosure do not limit the detection region.

The color-filter structure detection method provided by the embodiments of the present disclosure is used to detect the color-filter structures of the array substrate provided by any embodiment of the present disclosure, and has corresponding technical features and beneficial effects. Contents not described in detail in the embodiments of the color-filter structure detection method may refer to the above description of the array substrate and are not repeated here. Similarly, the array substrate provided by the embodiments of the present disclosure also has functional modules and beneficial effects for performing the color-filter structure detection method. Contents not described in detail in the embodiments of the array substrate may refer to the above description of the color-filter structure detection method and are not repeated here.

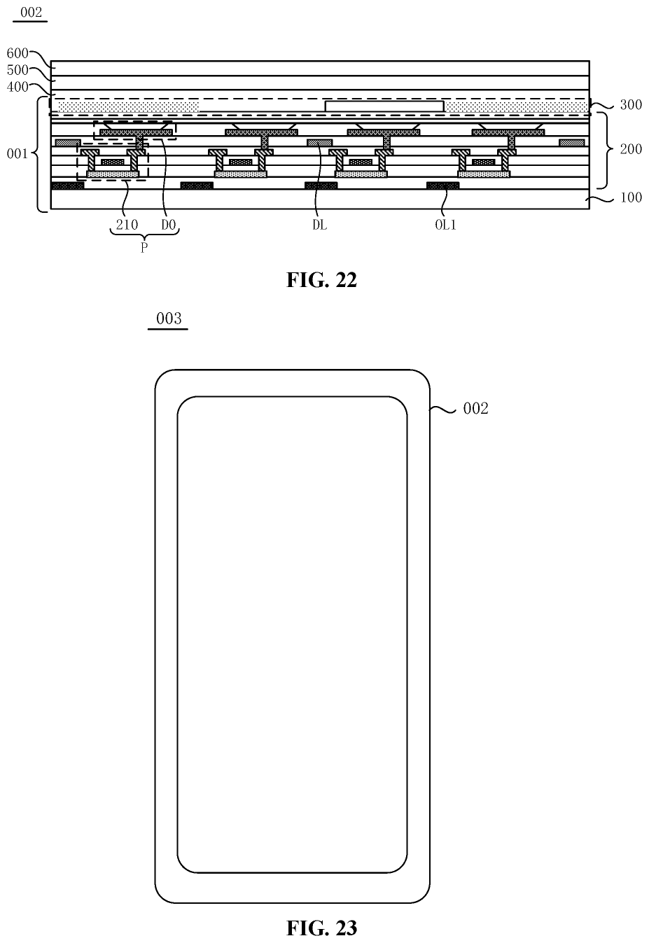

The embodiments of the present disclosure also provide a display panel. FIG. 22 is a structural schematic diagram of a display panel according to an embodiment of the present disclosure. As shown in FIG. 22, and the display panel 002 includes an array substrate 001 provided by any embodiment of the present disclosure.

The display panel 002 provided by the embodiments of the present disclosure may be a liquid crystal display panel, where the color-filter layer 300 is located on the array substrate 001. Alternatively, the display panel 002 may be an OLED display panel, for example, a WOLED display panel. Alternatively, the display panel 002 may be a Mini LED display panel or a Micro LED display panel. The embodiments of the present disclosure do not limit the type of the display panel 002.

For example, taking the display panel 002 as a WOLED display panel, referring to FIG. 22, the display panel 002 further includes a planarization layer 400, an optical functional layer 500, and a cover plate 600 located on a side of the color-filter layer 300 facing away from the substrate.

Based on the same inventive concept, the embodiments of the present disclosure also provide a display device. FIG. 23 is a structural schematic diagram of a display device according to an embodiment of the present disclosure. As shown in FIG. 23, the display device 003 includes the display panel 002 provided by any embodiment of the present disclosure. The display device 003 may be a mobile phone as shown in FIG. 23, or may be any electronic product with a display function, including but not limited to: a television, a notebook computer, a desktop display, a tablet computer, a digital camera, a smart bracelet, smart glasses, an in-vehicle display, medical equipment, industrial control equipment, and a touch interactive terminal. The embodiments of the present disclosure do not impose special limitations thereto.

Note that the above are only preferred embodiments of the present disclosure and applied technical principles. Those skilled in the art will understand that the present disclosure is not limited to the specific embodiments described herein, and various obvious changes, readjustments, and substitutions may be made without departing from the scope of protection of the present disclosure. Therefore, although the present disclosure has been described in detail through the above embodiments, the present disclosure is not limited to the above embodiments, but may include other equivalent embodiments without departing from the concept of the present disclosure, and the scope of the present disclosure is determined by the appended claims.

What is claimed is:

1. An array substrate, comprising:
a substrate;
a plurality of sub-pixels;
a light-emitting functional layer located on a side of the substrate; and
a color-filter layer located on a side of the light-emitting functional layer facing away from the substrate;
wherein the light-emitting functional layer comprises a plurality of pixel columns arranged along a first direction and extending along a second direction and a plurality of data signal lines arranged along the first direction and extending along the second direction,
the first direction intersects the second direction, and both the first direction and the second direction are parallel to a plane of the substrate, and
one of the plurality of pixel columns comprises more than one of the plurality of sub-pixels arranged along the second direction, and at least one of the plurality of data signal lines is electrically connected to sub-pixels in two of the plurality of pixel columns;
wherein the array substrate further comprises a plurality of first light-shielding lines located on a side of the color-filter layer facing the substrate, arranged along the first direction and extending along the second direction, and
orthographic projections of the plurality of data signal lines on the plane of the substrate overlap orthographic projections of the plurality of first light-shielding lines on the plane of the substrate; and
wherein the color-filter layer is located in a display area, and the color-filter layer comprises a plurality of color-filter structures,
orthographic projections of the plurality of color-filter structures on the plane of the substrate overlap orthographic projections of the plurality of sub-pixels on the plane of the substrate,
one of the plurality of color-filter structures comprises a first edge and a second edge arranged opposite to each other along the first direction; and an orthographic projection of the first edge on the plane of the substrate and an orthographic projection of the second edge on the plane of the substrate overlap the orthographic projections of the plurality of first light-shielding lines on the plane of the substrate.

2. The array substrate according to claim 1, wherein
along the first direction, adjacent color-filter structures of the plurality of color-filter structures have different colors; and
an orthographic projection of a color-filter structure of the plurality of color-filter structures on the plane of the substrate covers orthographic projections of more than one of the plurality of sub-pixels arranged along the second direction on the plane of the substrate.

3. The array substrate according to claim 1, wherein
along the second direction, a length of a first light-shielding line of the plurality of first light-shielding lines is greater than a length of a color-filter structure of the plurality of color-filter structures.

4. The array substrate according to claim 1, wherein
an orthographic projection of one of the plurality of color-filter structures on the plane of the substrate overlaps orthographic projections of only two adjacent ones of the plurality of first light-shielding lines arranged along the first direction on the plane of the substrate;
or, wherein
an orthographic projection of only one of the plurality of first light-shielding lines on the plane of the substrate exists between an orthographic projection of one of two adjacent ones of the plurality of pixel columns arranged along the first direction on the plane of the substrate.

5. The array substrate according to claim 1, wherein
the plurality of data signal lines also serve as more than one of the plurality of first light-shielding lines;
wherein the array substrate further comprises a plurality of power signal lines and a plurality of reset signal lines, and
the array substrate comprises at least one of the following: the plurality of power signal lines also serves as more than one of the plurality of first light-shielding lines, or the plurality of reset signal lines also serves as more than one of the plurality of first light-shielding lines; and
wherein along the first direction, the array substrate comprises at least one of the following: one of the plurality of power signal lines is located between two adjacent ones of the plurality of data signal lines, or, one of the plurality of reset signal lines is located between two adjacent ones of the plurality of data signal lines.

6. The array substrate according to claim 5, wherein both the plurality of power signal lines and the plurality of reset signal lines also serve as more than one of the plurality of first light-shielding lines, and
the plurality of power signal lines and the plurality of reset signal lines are alternately arranged along the first direction.

7. The array substrate according to claim 1, wherein
the plurality of first light-shielding lines comprise first-type light-shielding lines and second-type light-shielding lines; and
along the first direction, lengths of the first-type light-shielding lines are greater than lengths of the second-type light-shielding lines.

8. The array substrate according to claim 7, wherein
the first-type light-shielding lines also serve as more than one of the plurality of power signal lines, and
at least one of the second-type light-shielding lines also serves as at least one of the plurality of data signal lines.

9. The array substrate according to claim 8, wherein
the array substrate comprises a plurality of pixel units arranged in an array in the display area; and
one of the plurality of pixel units comprises a first-color sub-pixel, a second-color sub-pixel, a third-color sub-pixel and a fourth-color sub-pixel arranged along the first direction;
wherein the orthographic projection of one of the first-type light-shielding lines on the plane of the substrate is located between an orthographic projection of the first-color sub-pixel on the plane of the substrate and an orthographic projection of the fourth-color sub-pixel on the plane of the substrate; and
wherein the second-type light-shielding lines comprise a first routing line, a second routing line and a third routing line,
an orthographic projection of the first routing line on the plane of the substrate is located between the orthographic projection of the first-color sub-pixel on the plane of the substrate and an orthographic projection of the second-color sub-pixel on the plane of the substrate,
an orthographic projection of the second routing line on the plane of the substrate is located between the orthographic projection of the second-color sub-pixel on the plane of the substrate and an orthographic projection of the third-color sub-pixel on the plane of the substrate, and
an orthographic projection of the third routing line on the plane of the substrate is located between the orthographic projection of the third-color sub-pixel on the plane of the substrate and the orthographic projection of the fourth-color sub-pixel on the plane of the substrate; and
wherein the first routing line and the third routing line each also serve as a data signal line of the plurality of data signal lines, and the second routing line also serves as a reset signal line of the plurality of reset signal lines.

10. The array substrate according to claim 9, wherein
along the first direction, a length of the second routing line is greater than a length of the first routing line, and the length of the second routing line is greater than a length of the third routing line.

11. The array substrate according to claim 1, wherein
the light-emitting functional layer comprises a plurality of light-emitting elements and a pixel driving circuit;
the array substrate further comprises a black light-shielding layer;
the black light-shielding layer comprises a plurality of first light-shielding portions arranged along the first direction and extending along the second direction;
an orthographic projection of a first light-shielding portion of the plurality of first light-shielding portions on the plane of the substrate does not overlap an orthographic projection of a light-emitting element of the plurality of light-emitting elements on the plane of the substrate; and
the orthographic projection of the first light-shielding portion on the plane of the substrate overlaps an orthographic projection of a first light-shielding line the plurality of first light-shielding lines on the plane of the substrate; and
wherein the black light-shielding layer is located between the light-emitting functional layer and the color-filter layer; and
the plurality of first light-shielding lines also serve as more than one of the plurality of first light-shielding portions.

12. The array substrate according to claim 1, wherein
along the second direction, adjacent color-filter structures have different colors,
the array substrate further comprises a plurality of second light-shielding lines located on a side of the color-filter layer facing the substrate, arranged along the second direction and extending along the first direction;
one of the plurality of color-filter structures comprises a third edge and a fourth edge arranged opposite to each other along the second direction, and
an orthographic projection of the third edge and an orthographic projection of the fourth edge on the plane of the substrate overlaps orthographic projections of the plurality of second light-shielding lines on the plane of the substrate.

13. The array substrate according to claim 12, wherein
the light-emitting functional layer further comprises a plurality of second signal lines extending along the first direction, and
along the second direction, lengths of the plurality of second light-shielding lines are greater than lengths of the plurality of second signal lines.

14. The array substrate according to claim 12, wherein
at least one of the plurality of second light-shielding lines and at least one of the plurality of first light-shielding lines are disposed in a same layer.

15. The array substrate according to claim 1, wherein one of the plurality of color-filter structure comprises a first color-filter portion and a second color-filter portion arranged along the second direction; and
along the first direction, a length of the first color-filter portion and a length of the second color-filter portion are different.

16. The array substrate according to claim 1, wherein
the plurality of color-filter structures have different colors, and at least two of the the plurality of color-filter structures of different colors have different thicknesses along a direction perpendicular to the plane of the substrate.

17. The array substrate according to claim 1, wherein
one of the plurality of color-filter structures comprises a third color-filter portion and a fourth color-filter portion,
an orthographic projection of the fourth color-filter portion on the plane of the substrate at least partially surrounds an orthographic projection of the third color-filter portion on the plane of the substrate, and
along a direction perpendicular to the plane of the substrate, a thickness of the third color-filter portion is not equal to a thickness of the fourth color-filter portion.

18. A display panel comprising an array substrate, wherein the array substrate comprises:
a substrate;
a plurality of sub-pixels;
a light-emitting functional layer located on a side of the substrate; and
a color-filter layer located on a side of the light-emitting functional layer facing away from the substrate;
wherein the light-emitting functional layer comprises a plurality of pixel columns arranged along a first direction and extending along a second direction and a plurality of data signal lines arranged along the first direction and extending along the second direction,
the first direction intersects the second direction, and both the first direction and the second direction are parallel to a plane of the substrate, and
one of the plurality of pixel columns comprises more than one of the plurality of sub-pixels arranged along the second direction, and at least one of the plurality of data signal lines is electrically connected to sub-pixels in two of the plurality of pixel columns;
wherein the array substrate further comprises a plurality of first light-shielding lines located on a side of the color-filter layer facing the substrate, arranged along the first direction and extending along the second direction, and
orthographic projections of the plurality of data signal lines on the plane of the substrate overlap orthographic projections of the plurality of first light-shielding lines on the plane of the substrate; and
wherein the color-filter layer is located in a display area, and the color-filter layer comprises a plurality of color-filter structures,
orthographic projections of the plurality of color-filter structures on the plane of the substrate overlap orthographic projections of the plurality of sub-pixels on the plane of the substrate,
one of the plurality of color-filter structures comprises a first edge and a second edge arranged opposite to each other along the first direction; and an orthographic projection of the first edge on the plane of the substrate and an orthographic projection of the second edge on the plane of the substrate overlap the orthographic projections of the plurality of first light-shielding lines on the plane of the substrate.

19. A display device comprising a display panel, wherein the display panel comprises an array substrate, and the array substrate comprises:
a substrate;
a plurality of sub-pixels;
a light-emitting functional layer located on a side of the substrate; and
a color-filter layer located on a side of the light-emitting functional layer facing away from the substrate;
wherein the light-emitting functional layer comprises a plurality of pixel columns arranged along a first direction and extending along a second direction and a plurality of data signal lines arranged along the first direction and extending along the second direction,
the first direction intersects the second direction, and both the first direction and the second direction are parallel to a plane of the substrate, and
one of the plurality of pixel columns comprises more than one of the plurality of sub-pixels arranged along the second direction, and at least one of the plurality of data signal lines is electrically connected to sub-pixels in two of the plurality of pixel columns;
wherein the array substrate further comprises a plurality of first light-shielding lines located on a side of the color-filter layer facing the substrate, arranged along the first direction and extending along the second direction, and
orthographic projections of the plurality of data signal lines on the plane of the substrate overlap orthographic projections of the plurality of first light-shielding lines on the plane of the substrate; and
wherein the color-filter layer is located in a display area, and the color-filter layer comprises a plurality of color-filter structures,
orthographic projections of the plurality of color-filter structures on the plane of the substrate overlaps orthographic projections of the plurality of sub-pixels on the plane of the substrate, one of the plurality of color-filter structures comprises a first edge and a second edge arranged opposite to each other along the first direction; and an orthographic projection of the first edge on the plane of the substrate and an orthographic projection of the second edge on the plane of the substrate overlap the orthographic projections of the plurality of first light-shielding lines on the plane of the substrate.

20. A color-filter structure detection method for the array substrate according to claim 1, comprising:
providing the array substrate, wherein the array substrate comprises the substrate, the light-emitting functional layer located on the side of the substrate, and the color-filter layer located on the side of the light-emitting functional layer facing away from the substrate;
providing a light source on a side of the substrate facing away from the color-filter layer, wherein light from the light source passes through the substrate, the light-emitting functional layer, and the color-filter layer sequentially;
capturing the array substrate at a side of the color-filter layer facing away from the substrate to acquire a detection image; and
determining whether a color-filter structure of the plurality of color-filter structures in the color-filter layer is misaligned based on contours of the plurality of color-filter structures and contours of the plurality of first light-shielding lines in the detection image.
